(19) United States
(12) Patent Application Publication
(10) Pub. No.: US 2019/0110012 A1
(43) Pub. Date: Apr. 11, 2019

(54) AD CONVERSION CIRCUIT AND IMAGING DEVICE

(71) Applicant: OLYMPUS CORPORATION, Tokyo (JP)

(72) Inventor: Yoshio Hagihara, Tokyo (JP)

(73) Assignee: OLYMPUS CORPORATION, Tokyo (JP)

(21) Appl. No.: 16/214,772

(22) Filed: Dec. 10, 2018

Related U.S. Application Data
(63) Continuation of application No. PCT/JP2016/070529, filed on Jul. 12, 2016.

(51) Int. Cl. H04N 5/378; H04N 5/374; H03M 1/12

(52) U.S. Cl. CPC H04N 5/378; H03M 1/123; H04N 5/374

(57) ABSTRACT

An analog-to digital (AD) conversion circuit includes a digital-to-analog (DA) conversion circuit, an arithmetic circuit, and a comparison circuit. The DA conversion circuit generates a first reference current signal. The arithmetic circuit is electrically connected to the DA conversion circuit and generates a comparison current signal by adding the first reference current signal to a first current signal generated in accordance with a first voltage signal or subtracting the first reference current signal from the first current signal. The comparison circuit is electrically connected to the arithmetic circuit and outputs digital data based on a result of comparing a second current signal according to a second voltage signal with the comparison current signal.

### BACKGROUND OF THE INVENTION

### Field of the Invention

The present invention relates to an analog-to digital (AD) conversion circuit and an imaging device.

The present application is a continuation application based on International Patent Application No. PCT/JP 2016/070529 filed on Jul. 12, 2016, the content of which is incorporated herein by reference.

### Description of Related Art

Physical quantity detection semiconductor devices having sensors sensitive to externally input electromagnetic waves (light, radiation, etc.) are used in various fields. A physical quantity is converted into an electrical signal by a sensor. For example, a sensor in an imaging device is a pixel. Generally, electrical signals of a reference level and a signal level are read from the sensor. For example, the reference level in the imaging device is a reset level. Particularly in the field of video devices, a charge coupled device (CCD) type or metal oxide semiconductor (MOS) type imaging device for detecting light as a physical quantity is used (see Non-Patent Literature 1). Light is an example of electromagnetic waves. A MOS type imaging device includes a so-called (C)MOS type imaging device including pixels of an active pixel sensor (APS) configuration. A pixel of the APS configuration amplifies a pixel signal according to signal charges generated by a photoelectric conversion unit and outputs the amplified pixel signal.

Non-Patent Literature 1: Martin Waeny, et al., “Ultrasmall digital image sensor for endoscopic applications,” HSW, June 2009.

In an endoscope system using an imaging device, it is important to reduce a size of the imaging device in order to reduce a size of an endoscope. Thus, a CCD type imaging device has been generally used. However, because an output of the CCD type imaging device is analog, a scope length of the endoscope becomes long, so degradation of image quality due to noise superimposition has been problematic. In recent years, in order to solve this problem, a digital output CMOS type imaging device in which an AD conversion circuit is embedded has been used.

### SUMMARY OF THE INVENTION

According to a first aspect of the present invention, an AD conversion circuit includes a digital-to-analog (DA) conversion circuit, an arithmetic circuit, and a comparison circuit. The DA conversion circuit generates a first reference current signal. The arithmetic circuit is electrically connected to the DA conversion circuit and generates a comparison current signal by adding the first reference current signal to a first current signal generated in accordance with a first voltage signal or subtracting the first reference current signal from the first current signal. The comparison circuit is electrically connected to the arithmetic circuit and outputs digital data based on a result of comparing a second current signal according to a second voltage signal with the comparison current signal.

According to a second aspect of the present invention, an imaging device includes the above-described AD conversion circuit, an imaging unit, a column circuit, a first current generation circuit, and a second current generation circuit. The imaging unit includes a plurality of pixels disposed in a matrix shape. Each pixel included in the plurality of pixels outputs a reset level and a signal level. The column circuit is electrically connected to the imaging unit and generates a first pixel signal according to the reset level and a second pixel signal according to the signal level. The first current generation circuit is electrically connected to the column circuit and generates a first pixel current signal according to the first pixel signal. The second current generation circuit is electrically connected to the column circuit and generates a second pixel current signal according to the second pixel signal. The arithmetic circuit is further electrically connected to one of the first current generation circuit and the second current generation circuit. The comparison circuit is further electrically connected to the other of the first current generation circuit and the second current generation circuit. The first current signal is one of the first pixel current signal and the second pixel current signal. The second current signal is the other of the first pixel current signal and the second pixel current signal.

According to a third aspect of the present invention, in the second aspect, the first current generation circuit may include a first transistor and a second transistor constituting a first current mirror circuit. The second current generation circuit may include a third transistor and a fourth transistor constituting a second current mirror circuit different from the first current mirror circuit.

According to a fourth aspect of the present invention, an imaging device includes the above-described AD conversion circuit, an image unit, a column circuit, a reference signal generation circuit, a first current generation circuit, and a second current generation circuit. The imaging unit includes a plurality of pixels disposed in a matrix shape. Each pixel included in the plurality of pixels outputs a reset level and a signal level. The column circuit is electrically connected to the imaging unit and generates a difference signal according to a difference between the reset level and the signal level. The reference signal generation circuit generates a reference signal. The first current generation circuit is electrically connected to the reference signal generation circuit and generates a second reference current signal according to the reference signal. The second current generation circuit is electrically connected to the column circuit and generates a difference current signal according to the difference signal. The arithmetic circuit is further electrically connected to one of the first current generation circuit and the second current generation circuit. The comparison circuit is further electrically connected to the other of the first current generation circuit and the second current generation circuit. The first current signal is one of the second reference current signal and the difference current signal. The second current signal is the other of the second reference current signal and the difference current signal.

According to a fifth aspect of the present invention, in the fourth aspect, the first current generation circuit may include a first transistor and a second transistor constituting a first current mirror circuit. The second current generation circuit may include a third transistor and a fourth transistor constituting a second current mirror circuit different from the first current mirror circuit.

### BRIEF DESCRIPTION OF THE DRAWINGS

FIG. 1 is a circuit diagram showing a configuration of an AD conversion circuit according to a first embodiment of the present invention.

FIG. 2 is a circuit diagram showing a configuration of an AD conversion circuit according to a modified example of the first embodiment of the present invention.

FIG. 3 is a block diagram showing a configuration of an imaging device according to a second embodiment of the present invention.

FIG. 4 is a circuit diagram showing a configuration of a pixel according to the second embodiment of the present invention.

FIG. 5 is a circuit diagram showing a configuration of a column circuit according to the second embodiment of the present invention.

FIG. 6 is a circuit diagram showing a configuration of an output unit according to the second embodiment of the present invention.

FIG. 7 is a timing chart showing an operation of the imaging device according to the second embodiment of the present invention.

FIG. 8 is a circuit diagram showing a configuration of an output unit according to a first modified example of the second embodiment of the present invention.

FIG. 9 is a circuit diagram showing a configuration of a column circuit according to a second modified example of the second embodiment of the present invention.

FIG. 10 is a circuit diagram showing a configuration of an output unit according to the second modified example of the second embodiment of the present invention.

FIG. 11 is a circuit diagram showing a configuration of an output unit according to a third modified example of the second embodiment of the present invention.

FIG. 12 is a block diagram showing a configuration of an imaging device according to a third embodiment of the present invention.

FIG. 13 is a circuit diagram showing a configuration of a column circuit according to the third embodiment of the present invention.

FIG. 14 is a circuit diagram showing a configuration of an output unit according to the third embodiment of the present invention.

FIG. 15 is a timing chart showing an operation of the imaging device according to the third embodiment of the present invention.

FIG. 16 is a circuit diagram showing a configuration of an output unit according to a first modified example of the third embodiment of the present invention.

FIG. 17 is a block diagram showing a configuration of an imaging device according to a second modified example of the third embodiment of the present invention.

FIG. 18 is a circuit diagram showing a configuration of a column circuit according to the second modified example of the third embodiment of the present invention.

FIG. 19 is a circuit diagram showing a configuration of an output unit according to the second modified example of the third embodiment of the present invention.

FIG. 20 is a circuit diagram showing a configuration of an output unit according to a third modified example of the third embodiment of the present invention.

FIG. 21 is a block diagram showing a configuration of an imaging device according to a fourth modified example of the third embodiment of the present invention.

FIG. 22 is a block diagram showing a configuration of an endoscope system according to a fourth embodiment of the present invention.

### DETAILED DESCRIPTION OF THE INVENTION

Embodiments of the present invention will be described with reference to the drawings.

### First Embodiment

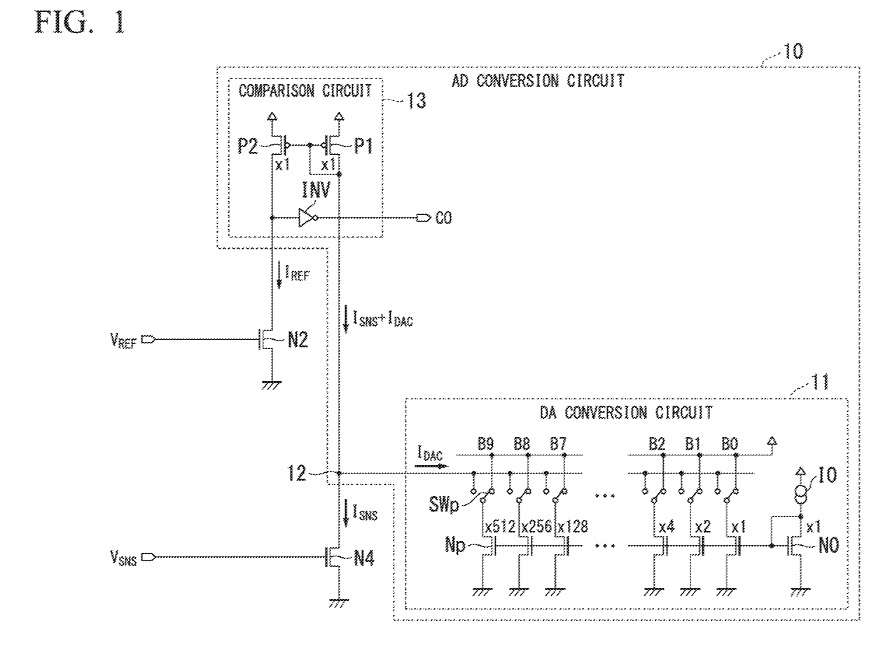

FIG. 1 shows a configuration of an AD conversion circuit 10 according to a first embodiment of the present invention. As shown in FIG. 1, the AD conversion circuit 10 includes a DA conversion circuit 11, an arithmetic circuit 12, and a comparison circuit 13.

A schematic configuration of the AD conversion circuit 10 will be described. The DA conversion circuit 11 generates a first reference current signal. The arithmetic circuit 12 is electrically connected to the DA conversion circuit 11 and generates a comparison current signal by adding the first reference current signal to a first current signal generated in accordance with a first voltage signal. The comparison circuit 13 is electrically connected to the arithmetic circuit 12 and outputs digital data based on a result of comparing a second current signal according to a second voltage signal with the comparison current signal.

A detailed configuration of the AD conversion circuit 10 will be described. The DA conversion circuit 11 has a current source I0, a transistor N0, a plurality of transistors Np, and a plurality of switches SWp. In FIG. 1, reference signs of one transistor Np and one switch SWp are shown as representatives.

A current source I0 includes a first terminal and a second terminal. The first terminal of the current source I0 is connected to a power supply configured to output a power-supply voltage. The transistor N0 and the transistor Np are NMOS transistors. Each of the transistor N0 and the transistor Np includes a gate terminal, a source terminal, and a drain terminal. The drain terminal of the transistor N0 is connected to the second terminal of the current source I0. The source terminal of the transistor N0 is connected to the ground. The gate terminal of the transistor N0 is connected to the drain terminal of the transistor N0. The drain terminal of the transistor Np is connected to the switch SWp. The source terminal of the transistor Np is connected to the ground. The gate terminal of the transistor Np is connected to the gate terminal of the transistor N0. The switch SWp has a first terminal, a second terminal, and a third terminal. The first terminal of the switch SWp is connected to the arithmetic circuit 12. The second terminal of the switch SWp is connected to a power supply configured to output a power-supply voltage. The third terminal of the switch SWp is connected to the drain terminal of the transistor Np.

A reference current generated by the current source I0 flows between the drain terminal of the transistor N0 and the source terminal of the transistor N0. The transistor NO and the transistor Np constitute a current mirror circuit. A current corresponding to a mirror ratio of the transistor N0 and the transistor Np flows between the drain terminal of the transistor Np and the source terminal of the transistor Np. In FIG. 1, the mirror ratio is set so that a current value of the current flowing through the transistor Np becomes a power of 2 of the current value of the reference current. A current amplification factor based on the reference current is stated in the vicinity of each transistor. The transistor Np is disposed for each of bits B0 to B9 constituting the digital data. The transistor Np having a largest current amplification factor corresponds to the bit B9 which is a most significant bit (MSB). A current whose current value is 512 times the current value of the reference current flowing through the transistor N0 flows through the transistor Np corresponding to the bit B9. The transistor Np having a smallest current amplification factor corresponds to the bit B0 which is a least significant bit (LSB). A current whose current value is the same as the current value of the reference current flowing through the transistor N0 flows through the transistor Np corresponding to the bit B0.

The switch SWp is disposed for each of the bits B0 to B9. The switch SWp is in one of a first state and a second state. When the switch SWp is in the first state, the first terminal and the third terminal of the switch SWp are electrically connected and the second terminal and the third terminal of the switch SWp are electrically insulated from each other. At this time, the transistor Np connected to the switch SWp is electrically connected to the arithmetic circuit 12. Thus, the current flowing through the transistor Np is supplied to the arithmetic circuit 12. When the switch SWp is in the second state, the second terminal and the third terminal of the switch SWp are electrically connected and the first terminal and the third terminal of the switch SWp are electrically insulated from each other. At this time, the transistor Np connected to the switch SWp is electrically insulated from the arithmetic circuit 12. Thus, the current flowing through the transistor Np connected to the switch SWp is not supplied to the arithmetic circuit 12. The state of the switch SWp is controlled according to a control signal (not shown). A first reference current signal which is a sum of currents flowing through the transistor Np connected to the switch SWp in the first state is supplied to the arithmetic circuit 12. The current value of the first reference current signal is I_{DAC}.

The control signal for controlling the switch SWp constitutes the digital data corresponding to the bits B0 to B9. The DA conversion circuit 11 converts the digital data into the first reference current signal which is an analog signal and supplies the first reference current signal to the arithmetic circuit 12. The current value of the first reference current signal supplied to the arithmetic circuit 12 is based on the state of each switch SWp. The DA conversion circuit 11 generates the first reference current signal having a plurality of current values.

The arithmetic circuit 12 is connected to the transistor N4 disposed outside the AD conversion circuit 10. The first current signal generated by the transistor N4 and the first reference current signal generated by the DA conversion circuit 11 are supplied to the arithmetic circuit 12. The current value of the first current signal generated by the transistor N4 is I_{SNS}. The arithmetic circuit 12 generates a comparison current signal by adding the first current signal to the first reference current signal. The current value of the comparison current signal is (I_{SNS}+I_{DAC}). The arithmetic circuit 12 includes a node connected to the transistor N4, the DA conversion circuit 11, and the comparison circuit 13. That is, the arithmetic circuit 12 is a connection point of a signal line connected to the transistor N4, a signal line connected to the DA conversion circuit 11, and a signal line connected to the comparison circuit 13. The configuration of the arithmetic circuit 12 is not limited thereto. It is only necessary for the arithmetic circuit 12 to be a circuit configured to add the first current signal to the first reference current signal.

The comparison circuit 13 includes a transistor P1, a transistor P2, and an inverter circuit INV. The transistors P1 and P2 are PMOS transistors. Each of the transistor P1 and the transistor P2 includes a gate terminal, a source terminal, and a drain terminal. The source terminal of the transistor P1 is connected to a power supply configured to output a power-supply voltage. The drain terminal of the transistor P1 is connected to the arithmetic circuit 12. The gate terminal of the transistor P1 is connected to the drain terminal of the transistor P1. The source terminal of the transistor P2 is connected to a power supply configured to output the power-supply voltage. The drain terminal of the transistor P2 is connected to the transistor N2 disposed outside the AD conversion circuit 10. The gate terminal of the transistor P2 is connected to the gate terminal of the transistor P1. The inverter circuit INV includes an input terminal and an output terminal. The input terminal of the inverter circuit INV is connected to the drain terminal of the transistor P2.

The comparison current signal generated by the arithmetic circuit 12 and the second current signal generated by the transistor N2 are supplied to the comparison circuit 13. The current value of the second current signal generated by the transistor N2 is I_{REF}. In the description of the first embodiment, the current value (I_{SNS}) of the first current signal is assumed to be smaller than the current value (I_{REF}) of the second current signal. The comparison current signal flows between the source terminal of the transistor P1 and the drain terminal of the transistor P1. The transistor P1 and the transistor P2 constitute a current mirror circuit. A current according to the mirror ratio of the transistor P1 and the transistor P2 flows between the source terminal of the transistor P2 and the drain terminal of the transistor P2. In FIG. 1, an example in which tire mirror ratio of the transistor P1 and the transistor P2 is 1:1 is shown. The transistor P2 generates a current by returning the comparison current signal flowing through the transistor P1 in accordance with the mirror ratio of the transistor P1 and the transistor P2. In this example, a current whose current value is the same as the current value (I_{SNS}+I_{DAC}) of the comparison current signal flows between the source terminal of the transistor P2 and the drain terminal of the transistor P2.

The inverter circuit INV detects the drain voltage of the transistor P2 and the drain voltage of the transistor N2 and compares the detected voltages. Thereby, the inverter circuit INV compares the comparison current signal with the second current signal. The inverter circuit INV outputs a signal CO indicating the comparison result. For example, the threshold value of the input voltage of the inverter circuit INV is a voltage value which is half the power-supply voltage. When the current value (I_{SNS}+I_{DAC}) of the comparison current signal is larger than the current value (I_{REF}) of the second current signal, a high-level voltage signal is input to the input terminal of the inverter circuit INV. In this case, the inverter circuit INV outputs a low-level signal CO from an output terminal thereof. When the current value (I_{SNS}+I_{DAC}) of the comparison current signal is smaller than the current value (I_{REF}) of the second current signal, a low-level voltage signal is input to the input terminal of the inverter circuit INV. In this case, the inverter circuit INV outputs a high-level signal CO from the output terminal thereof. The signal CO constitutes the digital data which is the output of the AD conversion circuit 10.

A plurality of inverter circuits INV may be connected in series. The inverter circuit INV may be configured as a clocked inverter circuit to minimize malfunctions due to a change in the output. This is only an example and the present invention is not limited thereto.

For example, the DA conversion circuit 11, the arithmetic circuit 12, and the comparison circuit 13 are disposed on the same substrate. When a chip on which the AD conversion circuit 10 is disposed includes a plurality of substrates, the DA conversion circuit 11, the arithmetic circuit 12, and the comparison circuit 13 may be distributed to the plurality of substrates.

The transistor N2 and the transistor N4 are NMOS transistors. Each of the transistor N2 and the transistor N4 includes a gate terminal, a source terminal, and a drain terminal. The drain terminal of the transistor N2 is connected to the drain terminal of the transistor P2. The source terminal of the transistor N2 is connected to the ground. The second voltage signal is input to the gate terminal of the transistor N2. For example, the second voltage signal is a voltage signal of a reference level output from the sensor. The voltage value of the second voltage signal is V_{REF}. The drain terminal of the transistor N4 is connected to the arithmetic circuit 12. The source terminal of the transistor N4 is connected to the round. A first voltage signal is input to the gate terminal of the transistor N4. For example, the first voltage signal is a voltage signal of a signal level output from the sensor. The voltage value of the first voltage signal is V_{SNS}.

The transistor N4 generates a first current signal according to the first voltage signal and supplies the generated first current signal to the AD conversion circuit 10. The transistor N2 generates a second current signal according to the second voltage signal and supplies the generated second current signal to the AD conversion circuit 10.

At least one of the transistor N2 and the transistor N4 may be disposed on the substrate constituting the AD conversion circuit 10. That is, the AD conversion circuit 10 may include at least one of the transistor N2 and the transistor N4.

According to the above-described configuration, the AD conversion circuit 10 outputs digital data (a signal CO) according to the first voltage signal and the second voltage signal. The AD conversion circuit 10 may be embedded in the imaging device. In this case, at least one of the first voltage signal and the second voltage signal is a signal generated by the pixel.

An operation of the AD conversion circuit 10 will be described. The operation of the AD conversion circuit 10 is similar to that of a general successive approximation register (SAR) type ADC. Thus, a detailed description thereof will be omitted. The AD conversion circuit 10 sequentially changes a magnitude of the current value I_{DAC} of the first reference current signal from the MSB side to the LSB side and compares a magnitude of the current value (I_{SNS}+I_{DAC}) of the comparison current signal with a magnitude of the value (I_{REF}) of the second current signal. Thereby, the AD conversion circuit 10 performs a binary search. As a result, digital data according to the difference between the current value (I_{SNS}) of the first current signal and the current value (I_{REF}) of the second current signal is obtained.

First, the determination of the bit B9 is made. The switch SWp corresponding to the bit B9 is in the first state and the switches SWp corresponding to the bits B0 to B8 are in the second state. Thereby, the current flowing through the transistor Np connected to the switch SWp corresponding to the bit B9 is supplied as the first reference current signal to the arithmetic circuit 12. The inverter circuit INV compares the comparison current signal with the second current signals. The inverter circuit INV outputs a signal CO indicating the comparison result.

When the current value (I_{SNS}+I_{DAC}) of the comparison current signal is larger than the current value (I_{REF}) of the second current signal, the inverter circuit INV outputs a low-level signal CO from the output terminal thereof. In this case, when the determination of a bit lower than the bit B9 is made, the switch SWp corresponding to the bit B9 is kept in the second state. If the current value (I_{SNS}+I_{DAC}) of the comparison current signal is smaller than the current value (I_{REF}) of the second current signal, the inverter circuit INV outputs a high-level signal CO from the output terminal thereof. In this case, when the determination of a bit lower than the bit B9 is made, the switch SWp corresponding to the bit B9 is kept in the first state. The signal CO constitutes the digital data of the bit B9.

Next, the determination of the bit B8 is made. The switch SWp corresponding to the bit B8 is in the first state and the switches SWp corresponding to the bits B0 to B7 are in the second state. Thereby the current flowing through the transistor Np connected to the switch SWp corresponding to the bit B8 is added to the first reference current signal. The inverter circuit INV compares the comparison current signal with the second current sisal. The inverter circuit INV outputs a signal CO indicating the comparison result.

If the current value (I_{SNS}+I_{DAC}) of the comparison current signal is larger than the current value (I_{REF}) of the second current signal, the inverter circuit INV outputs the low-level signal CO from the output terminal thereof. In this case, when the determination of a bit lower than the bit B8 is made, the switch SWp corresponding to the bit B8 is kept in the second state. When the current value (I_{SNS}+I_{DAC}) of the comparison current signal is smaller than the current value (I_{REF}) of the second current signal, the inverter circuit INV outputs a high-level signal CO from the output terminal thereof. In this case, when the determination of a bit lower than the bit B8 is made, the switch SWp corresponding to the bit B8 is kept in the first state. The signal CO constitutes digital data of the bit B8.

The determination of bits from the bit B7 to the bit B0 is made as described above. When the determination of the bit B0 is completed, the AD conversion is completed.

The first voltage signal may be a voltage signal of a reference level and the second voltage signal may be a voltage signal of a signal level. The first voltage signal may be a voltage signal of a difference between the reference level and the signal level and the second voltage signal may be a voltage signal of a predetermined level. The first voltage signal may be a voltage signal of a predetermined level and the second voltage signal may be a voltage signal of a difference between the reference level and the signal level.

The DA conversion circuit 11 may be configured so that the current value of the first reference current signal increases or decreases at a fixed rate and the AD conversion circuit 10 may be configured so that a time until the signal CO output from the inverter circuit INV is inverted is measured. That is, the AD conversion circuit 10 may be configured as a single slope (SS) type analog-to-digital converter (ADC). Also, the present invention is not limited thereto.

In the above example, the AD conversion circuit 10 outputs 10-bit digital data. The number of bits may be changed by changing the number of transistors Np and the number of switches SWp in the DA conversion circuit 11. Each of the number of transistors Np and the number of switches SWp in the DA conversion circuit 11 may be 1. In this case, the DA conversion circuit 11 generates a first reference current signal having one current value, and the AD conversion circuit 10 outputs 1-bit digital data.

As described above, the arithmetic circuit 12 generates the comparison current signal by adding the first reference current signal to the first current signal generated in accordance with the first voltage signal. The comparison circuit 13 outputs digital data based on a result of comparing the second current signal according to the second voltage signal with the comparison current signal. Thereby, the AD conversion circuit 10 does not require a capacitive element having a large capacitance value. That is, it is possible to further reduce a size of the AD conversion circuit 10.

### Modified Example of First Embodiment

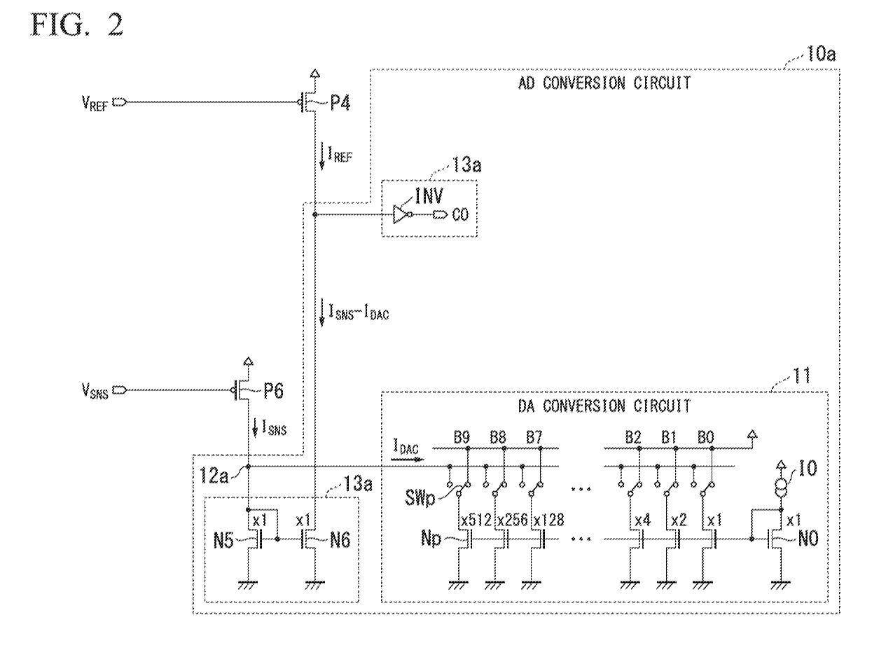

FIG. 2 shows a configuration of an AD conversion circuit 10a according to a modified example of the first embodiment of the present invention. Differences from the configuration shown in FIG. 1 will be described in terms of the configuration shown in FIG. 2.

In the AD conversion circuit 10a, the arithmetic circuit 12 in the AD conversion circuit 10 shown in FIG. 1 is changed to an arithmetic circuit 12a. In the AD conversion circuit 10a, the comparison circuit 13 in the AD conversion circuit 10 shown in FIG. 1 is changed to a comparison circuit 13a.

The arithmetic circuit 12a is connected to the transistor P6 disposed outside the AD conversion circuit 10a. The first current signal generated by the transistor P6 and the first reference current signal generated by the DA conversion circuit 11 are supplied to the arithmetic circuit 12a. The current value of the first current signal generated by the transistor P6 is I_{SNS}. The arithmetic circuit 12a generates a comparison current signal by subtracting the first reference current signal from the first current signal. The current value of the comparison current signal is (I_{SNS}−I_{DAC}). The arithmetic circuit 12a includes a node connected to the transistor P6, the DA conversion circuit 11, and the comparison circuit 13a. That is, the arithmetic circuit 12a is a connection point of a signal line connected to the transistor P6, a signal line connected to the DA conversion circuit 11, and a signal line connected to the comparison circuit 13a. The configuration of the arithmetic circuit 12a is not limited thereto. It is only necessary for the arithmetic circuit 12a to be a circuit configured to subtract the first reference current signal from the first current signal.

The comparison circuit 13a includes a transistor N5, a transistor N6, and an inverter circuit INV. The transistors N5 and N6 are NMOS transistors. Each of the transistor N5 and the transistor N6 includes a gate terminal, a source terminal, and a drain terminal. The source terminal of the transistor N5 is connected to the ground. The drain terminal of the transistor N5 is connected to the arithmetic circuit 12a. The gate terminal of the transistor N5 is connected to the drain terminal of the transistor N5. The source terminal of the transistor N6 is connected to the ground. The drain terminal of the transistor N6 is connected to the transistor P4 disposed outside the AD conversion circuit 10a. The gate terminal of the transistor N6 is connected to the gate terminal of the transistor N5. The inverter circuit INV has an input terminal and an output terminal. The input terminal of the inverter circuit INV is connected to the drain terminal of the transistor N5.

The comparison current signal generated by the arithmetic circuit 12a and the second current signal generated by the transistor P4 are supplied to the comparison circuit 13a. The current value of the second current signal generated by the transistor P4 is I_{REF}. In the description of the present modified example, the current value (I_{REF}) of the second current signal is assumed to be smaller than the current value (I_{SNS}) of the first current signal. The comparison current signal flows between the source terminal of the transistor N5 and the drain terminal of the transistor N5. The transistor N5 and the transistor N6 constitute a current mirror circuit. A current according to the mirror ratio of the transistor N5 and the transistor N6 flows between the drain terminal of the transistor N6 and the source terminal of the transistor N6. In FIG. 2, an example in which the mirror ratio of the transistor N5 and the transistor N6 is 1:1 is shown. The transistor N6 generates a current by returning the comparison current signal flowing through the transistor N5 in accordance with the mirror ratio of the transistor N5 and the transistor N6. In this example, a current whose current value is the sane as the current value (I_{SNS}−I_{DAC}) of the comparison current signal flows between the drain terminal of the transistor N6 and the source terminal of the transistor N6.

The inverter circuit INV detects a drain voltage of the transistor N6 and a drain voltage of the transistor P4 and compares the detected voltages. Thereby, the inverter circuit INV compares the comparison current signal with the second current signal. The inverter circuit INV outputs a signal CO indicating the comparison result. If the current value (I_{SNS}−I_{DAC}) of the comparison current signal is larger than the current value (I_{REF}) of the second current signal, a low-level voltage signal is input to the input terminal of the inverter circuit INV. In this case, the inverter circuit INV outputs a high-level signal CO from the output terminal thereof. If the current value (I_{SNS}−I_{DAC}) of the comparison current signal is smaller than the current value (I_{REF}) of the second current signal, high-level voltage signal is input to the input terminal of the inverter circuit INV. In this case, the inverter circuit INV outputs a low-level signal CO from the output terminal thereof. The signal CO constitutes digital data which is the output of the AD conversion circuit 10a.

The transistor P4 and the transistor P6 are PMOS transistors. Each of the transistor P4 and the transistor P6 includes a gate terminal, a source terminal, and a drain terminal. The drain terminal of the transistor P4 is connected to the drain terminal of the transistor N6. The source terminal of the transistor P4 is connected to a power supply configured to output a power-supply voltage. The second voltage signal is input to the gate terminal of the transistor P4. For example, the second voltage signal is a voltage signal of a reference level output from the sensor. The voltage value of the second voltage signal is V_{REF}. The drain terminal of the transistor P6 is connected to the arithmetic circuit 12a. The source terminal of the transistor P6 is connected to a power supply configured to output a power-supply voltage. The first voltage signal is input to the gate terminal of the transistor P6. For example, the first voltage signal is a voltage signal of a signal level output from the sensor. The voltage value of the first voltage signal is V_{SNS}.

The transistor P6 generates a first current signal according to the first voltage signal and supplies the generated first current signal to the AD conversion circuit 10a. The transistor P4 generates a second current signal according to the second voltage signal and supplies the generated second current signal to the AD conversion circuit 10a.

At least one of the transistor P4 and the transistor P6 may be disposed on the substrate constituting the AD conversion circuit 10a. That is, the AD conversion circuit 10a may include at least one of the transistor P4 and the transistor P6.

According to the above-described configuration, the AD conversion circuit 10a outputs digital data (a signal CO) corresponding to the first voltage signal and the second voltage signal. The AD conversion circuit 10a may be embedded in the imaging device. In that case, at least one of the first voltage signal and the second voltage signal is a signal generated by the pixel.

In terms of details other than the above, the configuration shown in FIG. 2 is similar to the configuration shown in FIG. 1.

The operation of the AD conversion circuit 10a is similar to the operation of the AD conversion circuit 10 shown in FIG. 1. Thus, a detailed description of the operation of the AD conversion circuit 10a will be omitted.

As described above, the arithmetic circuit 12a generates the comparison current signal by subtracting the first reference current signal from the first current signal generated in accordance with the first voltage signal. The comparison circuit 13a outputs digital data based on a result of comparing the second current signal according to the second voltage signal with the comparison current signal. Thereby, the AD conversion circuit 10a does not require a capacitive element having a large capacitance value. That is, it is possible to further reduce a size of the AD conversion circuit 10a.

### Second Embodiment

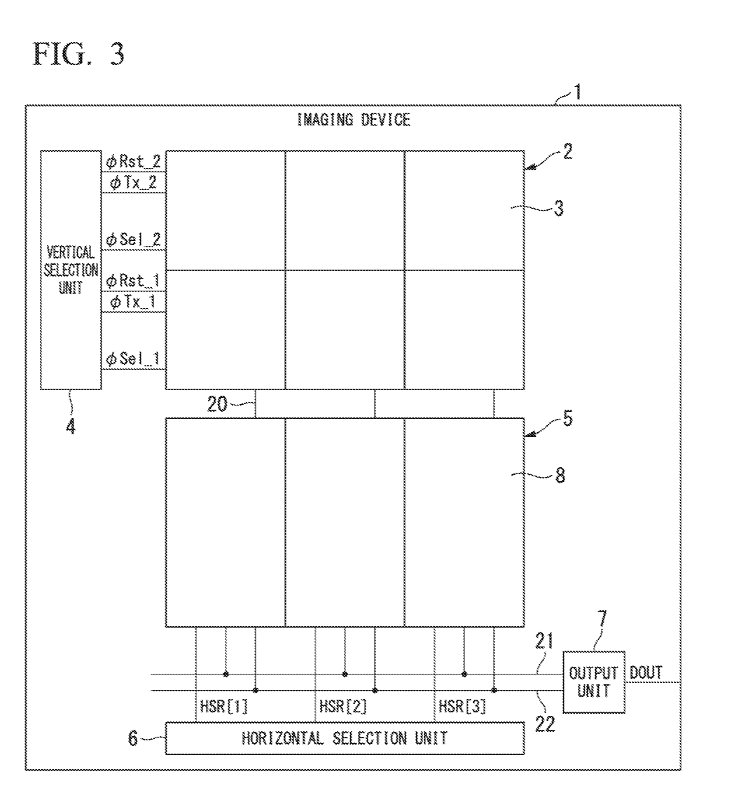

FIG. 3 shows a configuration of an imaging device 1 according to a second embodiment of the present invention. As shown in FIG. 3, the imaging device 1 includes an imaging unit 2, a vertical selection unit 4, a column circuit unit 5, a horizontal selection unit 6, and an output unit 7. For example, the imaging unit 2, the vertical selection unit 4, the column circuit unit 5, the horizontal selection unit 6, and the output unit 7 are disposed on the same substrate. When a chip on which the imaging device 1 is disposed includes a plurality of substrates, the imaging unit 2, the vertical selection unit 4, the column circuit unit 5, the horizontal selection unit 6, and the output unit 7 may be distributed to the plurality of substrates.

The imaging unit 2 includes a plurality of pixels 3 disposed in a matrix shape. The plurality of pixels 3 constitute an array of m rows and n columns. m and n are integers of 2 or more. The number of rows and the number of columns need not be the same. In FIG. 3, an example in which the number of rows is 2 and the number of columns is 3 is shown. This is only an example, and the present invention is not limited thereto. The pixel 3 outputs a reset level and a signal level.

The vertical selection unit 4 selects the pixel 3 disposed in a row direction in the array of the plurality of pixels 3. The vertical selection unit 4 controls an operation of the selected pixel 3. The vertical selection unit 4 outputs control signals for controlling the plurality of pixels 3 for each row in the array of the plurality of pixels 3. The control signals output from the vertical selection unit 4 include a transfer pulse ϕTx_i, a reset pulse ϕRst_i, and a selection pulse ϕSel_i. i is 1 or 2. In FIG. 3, the transfer pulse ϕTx_1, the reset pulse ϕRst_1, and the selection pulse ϕSel_1 are output to the pixels 3 of the first row. In FIG. 3, the transfer pulse ϕTx_2, the reset pulse ϕRst_2, and the selection pulse ϕSel_2 are output to the pixels 3 of the second row.

The column circuit unit 5 includes a plurality of column circuits 8. The column circuit 8 is disposed for each column in the array of the plurality of pixels 3. The column circuit 8 is connected to a vertical signal line 20 extending in a vertical direction, i.e., a column direction. The vertical signal line 20 is disposed for each column in the array of the plurality of pixels 3. The vertical signal line 20 is connected to the pixels 3 of each column. The column circuit 8 is electrically connected to the pixels 3 via the vertical signal line 20. The column circuit 8 generates a first pixel signal according to the reset level output from the pixel 3 and a second pixel signal according to the signal level output from the pixel 3. The column circuit 8 is connected to a horizontal signal line 21 and a horizontal signal line 22 extending in a horizontal direction, i.e., a row direction. A selection pulse HSR[k] from the horizontal selection unit 6 is output to the column circuit 8 corresponding to a column k. k is any one of 1, 2, and 3. The column circuit 8 selected by the selection pulse HSR[k] outputs a first pixel signal to the horizontal signal line 21 and outputs a second pixel signal to the horizontal signal line 22.

One column circuit 8 may be disposed for each of a plurality of columns in the array of the plurality of pixels 3 and one column circuit 8 may be used in a plurality of columns in a time-division manner.

The horizontal signal line 21 and the horizontal signal line 22 are connected to the output unit 7. The horizontal selection unit 6 sequentially selects the column circuits 8 according to the selection pulses HSR[1] to HSR[3]. The first pixel signal and the second pixel signal output from the column circuit 8 selected by the horizontal selection unit 6 are transferred to the output unit 7. The output unit 7 generates digital data DOUT according to the first pixel signal and the second pixel signal, and outputs the digital data DOUT to a circuit of a subsequent stage.

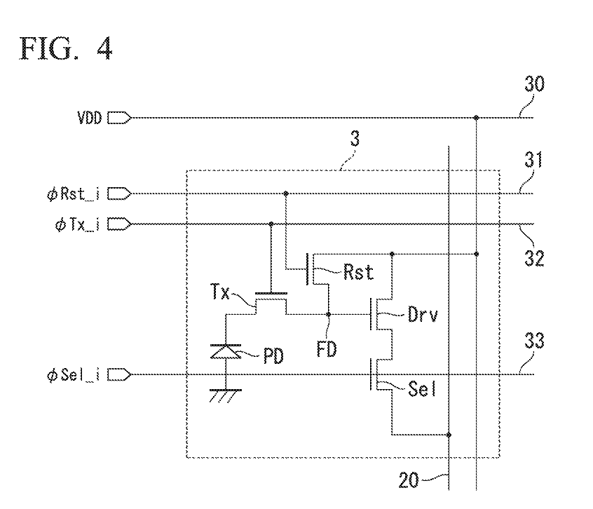

FIG. 4 shows a configuration of the pixel 3. The pixel 3 includes a photoelectric conversion unit PD, a transfer transistor Tx, a charge storage portion FD, a reset transistor Rst, an amplification transistor Drv, and a selection transistor Sel. Each transistor shown in FIG. 4 is an NMOS transistor. Each transistor shown in FIG. 4 includes a gate terminal, a source terminal, and a drain terminal.

For example, the photoelectric conversion unit PD is a photodiode. The photoelectric conversion unit PD has a first terminal and a second terminal. The first terminal of the photoelectric conversion unit PD is connected to the ground. The second terminal of the photoelectric conversion unit PD is connected to the transfer transistor Tx.

The drain terminal of the transfer transistor Tx is connected to the second terminal of the photoelectric conversion unit PD. The source terminal of the transfer transistor Tx is connected to the charge storage portion FD. The gate terminal of the transfer transistor Tx is connected to a control signal line 32. The control signal line 32 extends from the vertical selection unit 4 in the row direction in the array of the plurality of pixels 3. The control signal line 32 transmits the transfer pulse ϕTx_i.

The drain terminal of the reset transistor Rst is connected to a power supply line 30. The power supply line 30 is connected to a power supply configured to output a power-supply voltage VDD. The source terminal of the transistor Rst is connected to the charge storage portion FD. The gate terminal of the reset transistor Rst is connected to a control signal line 31. The control signal line 31 extends from the vertical selection unit 4 in the row direction in the array of the plurality of pixels 3. The control signal line 31 transmits the reset pulse ϕRst_i.

The drain terminal of the amplification transistor Drv is connected to the power supply line 30. The source terminal of the amplification transistor Drv is connected to the selection transistor Sel. The gate terminal of the amplification transistor Drv is connected to the charge storage portion FD.

The drain terminal of the selection transistor Sel is connected to the source terminal of the amplification transistor Drv. The source terminal of the selection transistor Sel is connected to the vertical signal line 20. The gate terminal of the selection transistor Sel is connected to a control signal line 33. The control signal line 33 extends from the vertical selection unit 4 in the row direction in the array of the plurality of pixels 3. The control signal line 33 transfers the selection pulse ϕSel_i.

The transfer transistor Tx is controlled according to the transfer pulse ϕTx_i output from the vertical selection unit 4. The transfer transistor Tx of the pixel 3 of the first row is controlled according to the transfer pulse ϕTx_1 and the transfer transistor Tx of the pixel 3 of the second row is controlled according to the transfer pulse ϕTx_2. The reset transistor Rst is controlled according to the reset pulse ϕRst_i output from the vertical selection unit 4. The reset transistor Rst of the pixel 3 of the first row is controlled according to the reset pulse ϕRst_1 and the reset transistor Rst of the pixel 3 of the second row is controlled according to the reset pulse ϕRst_2. The selection transistor Sel is controlled by the selection pulse ϕSel_i output from the vertical selection unit 4. The selection transistor Sel of the pixel 3 of the first row is controlled according to the selection pulse ϕSel_1 and the selection transistor Sel of the pixel 3 of the second row is controlled according to the selection pulse ϕSel_2.

The photoelectric conversion unit PD generates signal charges according to the amount of incident light. The transfer transistor Tx transfers the signal charges generated by the photoelectric conversion unit PD to the charge storage portion FD. For example, the charge storage portion FD is a floating diffusion. The charge storage portion FD stores the signal charges transferred by the transfer transistor Tx. The reset transistor Rst resets the charge storage portion FD to a predetermined voltage. The amplification transistor Drv amplifies a signal according to a voltage of the charge storage portion FD to generate a pixel signal. The selection transistor Sel outputs a pixel signal to the vertical signal line 20. The vertical signal line 20 is disposed for each column in the array of the plurality of pixels 3. The reset level and the signal level are output from the pixel 3 as pixel signals.

According to the above-described configuration, the plurality of pixels 3 output pixel signals according to incident light.

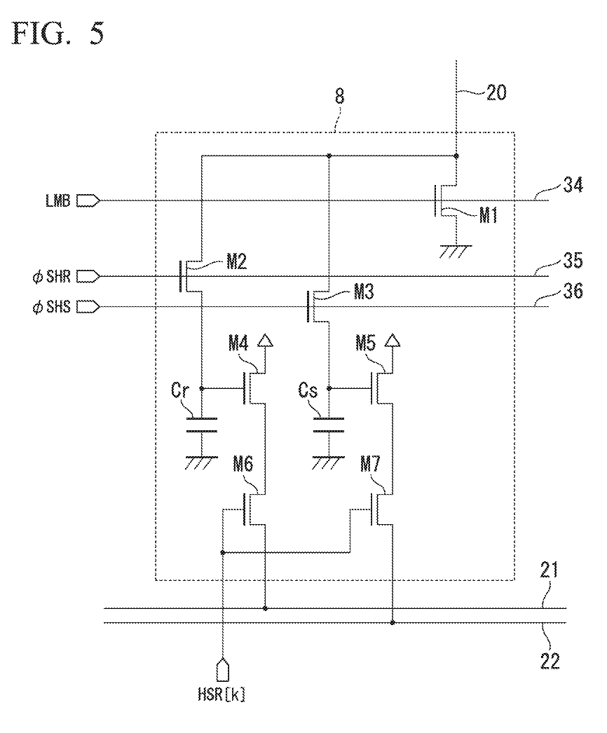

FIG. 5 shows a configuration of the column circuit 8. As shown in FIG. 5, the column circuit 8 includes a transistor M1, a sample transistor M2, a sample transistor M3, an amplification transistor M4, an amplification transistor M5, a column selection transistor M6, a column selection transistor M7, a capacitive element Cr, and a capacitive element Cs. Each transistor shown in FIG. 5 is an NMOS transistor. Each transistor shown in FIG. 5 includes a gate terminal, a source terminal, and a drain terminal.

The drain terminal of the transistor M1 is connected to the vertical signal line 20. The source terminal of the transistor M1 is connected to the ground. The gate terminal of the transistor M1 is connected to a power supply line 34. The power supply line 34 is connected to a power supply configured to output a predetermined voltage LMB.

The drain terminal of the sample transistor M2 is connected to the vertical signal line 20. The source terminal of the sample transistor M2 is connected to the capacitive element Cr. The gate terminal of the sample transistor M2 is connected to a control signal line 35. The control signal line 35 extends in the row direction in the array of the plurality of pixels 3. The control signal line 35 transfers a sample-and-hold pulse ϕSHR.

The drain terminal of the sample transistor M3 is connected to the vertical signal line 20. The source terminal of the sample transistor M3 is connected to the capacitive element Cs. The gate terminal of the sample transistor M3 is connected to a control signal line 36. The control signal line 36 extends in the row direction in the array of the plurality of pixels 3. The control signal line 36 transfers a sample-and-hold pulse ϕSHS.

The capacitive element Cr and the capacitive element Cs include a first terminal and a second terminal. The first terminal of the capacitive element Cr is connected to the source terminal of the sample transistor M2. The second terminal of the capacitive element Cr is connected to the ground. The first terminal of the capacitive element Cs is connected to the source terminal of the sample transistor M3. The second terminal of the capacitive element Cs is connected to the ground.

The drain terminal of the amplification transistor M4 is connected to a power supply configured to output a power-supply voltage. The source terminal of the amplification transistor M4 is connected to the column selection transistor M6. The gate terminal of the amplification transistor M4 is connected to the first terminal of the capacitive element Cr.

The drain terminal of the amplification transistor M5 is connected to a power supply configured to output a power-supply voltage. The source terminal of the amplification transistor M5 is connected to the column selection transistor M7. The gate terminal of the amplification transistor M5 is connected to the first terminal of the capacitive element Cs.

The drain terminal of the column selection transistor M6 is connected to the source terminal of the amplification transistor M4. The source terminal of the column selection transistor M6 is connected to the horizontal signal line 21. The gate terminal of the column selection transistor M6 is connected to the horizontal selection unit 6.

The drain terminal of the column selection transistor M7 is connected to the source terminal of the amplification transistor M5. The source terminal of the column selection transistor M7 is connected to the horizontal signal line 22. The gate terminal of the column selection transistor M7 is connected to the horizontal selection unit 6.

An operation of the sample transistor M2 is controlled according to the sample-and-hold pulse ϕSHR. An operation of the sample transistor M3 is controlled according to the sample-and-hold pulse ϕSHS. The column selection transistor M6 and the column selection transistor M7 are controlled according to the selection pulse HSR[k] output from the horizontal selection unit 6. k is any one of 1, 2, and 3.

The transistor M1 functions as a current source. The sample transistor M2 samples the pixel signal of the reset level output from the pixel 3 to the vertical signal line 20. The sample transistor M3 samples the pixel signal of the signal level output from the pixel 3 to the vertical signal line 20. The capacitive element Cr holds the pixel signal of the reset level sampled by the sample transistor M2. The capacitive element Cs holds the pixel signal of the signal level sampled by the sample transistor M3. The capacitive element Cr and the capacitive element Cs are sample capacitors. The amplification transistor M4 generates the first pixel signal by amplifying the pixel signal of the reset level held in the capacitive element Cr. That is, the amplification transistor M4 generates the first pixel signal based on the pixel signal of the reset level. The amplification transistor M5 generates the second pixel signal by amplifying the pixel signal of the signal level held in the capacitive element Cs. That is, the amplification transistor M5 generates the second pixel signal based on the pixel signal of the signal level. The column selection transistor M6 outputs the first pixel signal generated by the amplification transistor M4 to the horizontal signal line 21. The column selection transistor M7 outputs the second pixel signal generated by the amplification transistor M5 to the horizontal signal line 22. The column selection transistor M6 and the column selection transistor M7 of the first column are controlled according to a selection pulse HSR[1]. The column selection transistor M6 and the column selection transistor M7 of the second column are controlled according to a selection pulse HSR[2]. The column selection transistor M5 and the column selection transistor M7 of the third column are controlled according to a selection pulse HSR[3].

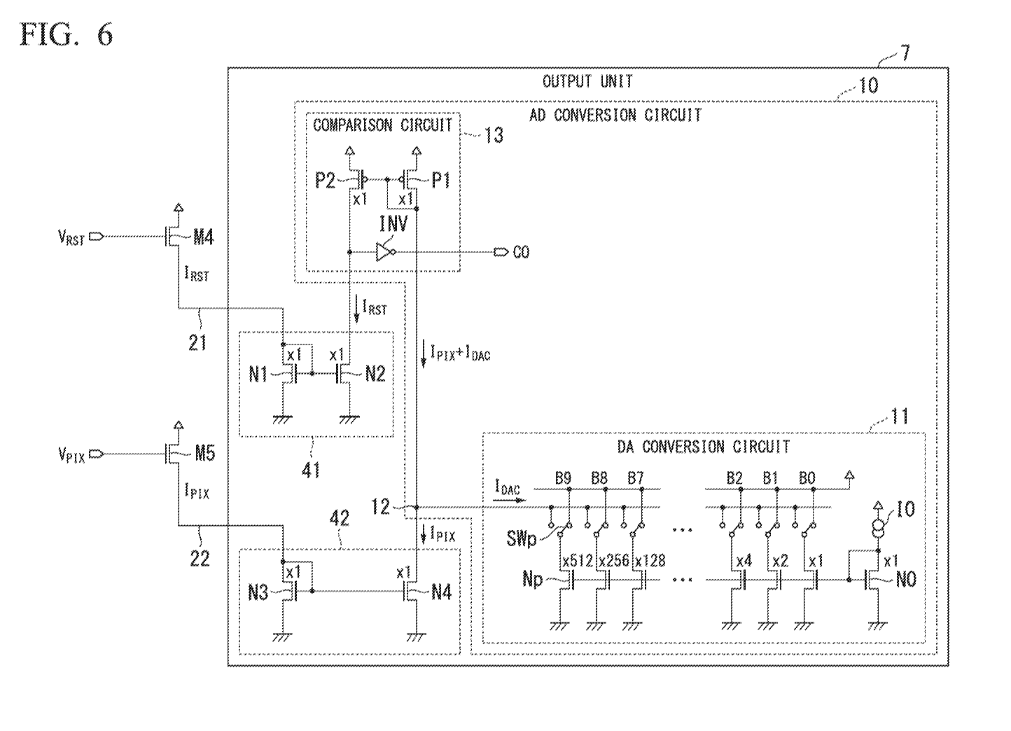

FIG. 6 shows the configuration of the output unit 7. As shown in FIG. 6, the output unit 7 includes an AD conversion circuit 10, a current generation circuit 41 (an impedance conversion circuit), and a current generation circuit 42 (an impedance conversion circuit). The configuration of the AD conversion circuit 10 shown in FIG. 6 is the same as that of the AD conversion circuit 10 shown in FIG. 1. Thus, a detailed description of the configuration of the AD conversion circuit 10 will be omitted.

The current generation circuit 41 includes a transistor N1 and a transistor N2. The transistors N1 and N2 are MOS transistors. Each of the transistor N1 and the transistor N2 includes a gate terminal, a source terminal, and a drain terminal. The drain terminal of the transistor N1 is connected to the horizontal signal line 21. The source terminal of the transistor N1 is connected to the ground. The gate terminal of the transistor N1 is connected to the drain terminal of the transistor N1. The drain terminal of the transistor N2 is connected to the drain terminal of the transistor P2 of the comparison circuit 13. The source terminal of the transistor N2 is connected to the ground. The gate terminal of the transistor N2 is connected to the gate terminal of the transistor N1.

The horizontal signal line 21 is connected to the column circuit 8. Thus, the current generation circuit 41 is electrically connected to the column circuit 8 via the horizontal signal line 21.

The first pixel signal output from the amplification transistor M4 of the column circuit 8 to the horizontal signal line 21 via the column selection transistor M6 is input to the current generation circuit 41. In FIG. 6, the column selection transistor M6 is not shown. The first pixel signal is based on the pixel signal of the reset level (V_{RST}). The current value of the first pixel signal is I_{RST}. The first pixel signal flows between the drain terminal of the transistor N1 and the source terminal of the transistor N1. The transistor N1 and the transistor N2 constitute a current mirror circuit. A current according to the mirror ratio of the transistor N1 and the transistor N2 flows between the drain terminal of the transistor N2 and the source terminal of the transistor N2. In FIG. 6, an example in which the mirror ratio of the transistor N1 and the transistor N2 is 1:1 is shown. The transistor N2 generates the first pixel current signal by returning the first pixel signal flowing through the transistor N1 in accordance with the mirror ratio of the transistor N1 and the transistor N2. In this example, a current whose current value is the same as the current value (I_{RST}) of the first pixel signal flows between the drain terminal of the transistor N2 and the source terminal of the transistor N2. The mirror ratio of the transistor N1 and the transistor N2 is not limited to 1:1. By changing the mirror ratio of the transistor N1 and the transistor N2, the current generation circuit 41 can have a signal amplification function.

The first pixel current signal generated by the transistor N2 is supplied to the comparison circuit 13. According to the above-described configuration, the current generation circuit 41 generates the first pixel current signal according to the first pixel signal.

The current generation circuit 42 includes a transistor N3 and a transistor N4. The transistor N3 and the transistor N4 are NMOS transistors. Each of the transistor N3 and the transistor N4 includes a gate terminal, a source terminal, and a drain terminal. The drain terminal of the transistor N3 is connected to the horizontal signal line 22. The source terminal of the transistor N3 is connected to the ground. The gate terminal of the transistor N3 is connected to the drain terminal of the transistor N3. The drain terminal of the transistor N4 is connected to the arithmetic circuit 12. The source terminal of the transistor N4 is connected to the ground. The gate terminal of the transistor N4 is connected to the gate terminal of the transistor N3.

The horizontal signal line 22 is connected to the column circuit 8. Thus, the current generation circuit 42 is electrically connected to the column circuit 8 via the horizontal signal line 22.

The second pixel signal output from the amplification transistor M5 of the column circuit 8 to the horizontal signal line 22 via the column selection transistor M7 is input to the current generation circuit 42. In FIG. 6, the column selection transistor M7 is not shown. The second pixel signal is based on the pixel signal of the signal level (V_{PIX}). The current value of the second pixel signal is I_{PIX}. In the description of the second embodiment, the current value (I_{PIX}) of the second pixel signal is assumed to be smaller than the current value (I_{RST}) of the first pixel signal. The second pixel signal flows between the drain terminal of the transistor N3 and the source terminal of the transistor N3. The transistor N3 and the transistor N4 constitute a current mirror circuit. A current according to the mirror ratio of the transistor N3 and the transistor N4 flows between the drain terminal of the transistor N4 and the source terminal of the transistor N4. In FIG. 6, an example in which the mirror ratio of the transistor N3 and the transistor N4 is 1:1 is shown. The transistor N4 generates the second pixel current signal by returning the second pixel signal flowing through the transistor N3 in accordance with the mirror ratio of the transistor N3 and the transistor N4. In this example, a current whose current value is the same as the current value (I_{PIX}) of the second pixel signal flows between the drain terminal of the transistor N4 and the source terminal of the transistor N4. The mirror ratio of the transistor N3 and the transistor N4 is not limited to 1:1. By changing the mirror ratio of the transistor N3 and the transistor N4, the current generation circuit 42 can have a signal amplification function.

The second pixel current signal generated by the transistor N4 is supplied to the arithmetic circuit 12. According to the above-described configuration, the current generation circuit 42 generates the second pixel current signal according to the second pixel signal.

If the mirror ratio of the transistor P1 and the transistor P2 is 1:1, the comparison circuit 13 outputs a signal CO according to a difference between the first pixel current signal generated by the transistor N2 and the second pixel current signal generated by the transistor N4. That is, the AD conversion circuit 10 can perform AD conversion on the difference between the first pixel current signal and the second pixel current signal. In addition, if the mirror ratio of the transistor N1 and the transistor N2 is the same as the mirror ratio of the transistor N3 and the transistor N4, the AD conversion circuit 10 performs AD conversion on the difference between the first pixel signal and the second pixel signal.

At least one of the current generation circuit 41 and the current generation circuit 42 may be disposed on the substrate constituting the AD conversion circuit 10. That is, the AD conversion circuit 10 may include at least one of the current generation circuit 41 and the current generation circuit 42.

In the AD conversion circuit 10, the arithmetic circuit 12 is electrically connected to the current generation circuit 42. The comparison circuit 13 is electrically connected to the current generation circuit 41. The second pixel current signal generated by the current generation circuit 42 is supplied as a first current signal to the arithmetic circuit 12. The first pixel current signal generated by the current generation circuit 41 is supplied as a second current signal to the comparison circuit 13.

The operation of the AD conversion circuit 10 shown in FIG. 6 is similar to the operation of the AD conversion circuit 10 shown in FIG. 1. Thus, a detailed description of the operation of the AD conversion circuit 10 shown in FIG. 6 will be omitted.

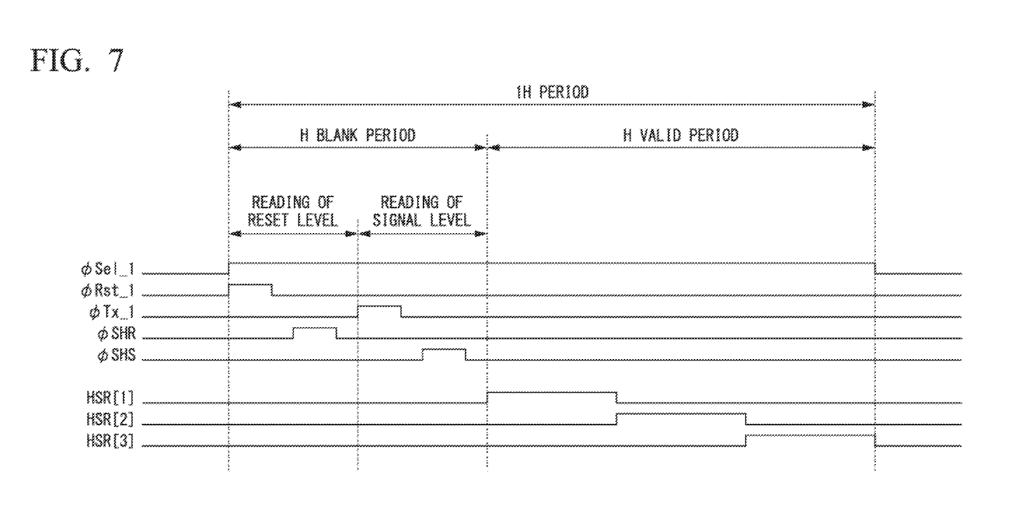

An operation of the imaging device 1 will be described. FIG. 7 shows the operation of the imaging device 1. Hereinafter, an operation in which the imaging device 1 reads a pixel signal will be described. As a representative, the operation of reading the pixel signal from the pixel 3 of the first row in the array of the plurality of pixels 3 will be described.

In FIG. 7, waveforms of the selection pulse ϕSel_1, the reset pulse ϕRst_1, the transfer pulse ϕTx_1, the sample-and-hold pulse ϕSHR, the sample-and-hold pulse ϕSHS, and the selection pulses HSR[1] to HSR[3] are shown. In FIG. 7, the horizontal direction represents time and the vertical direction represents voltage.

Before the pixel signal reading operation is started, the selection pulse ϕSel_1, the reset pulse ϕRst_1, the transfer pulse ϕTx_1, the sample-and-hold pulse ϕSHR, the sample-and-hold pulse ϕSHS, and the selection pulses HSR[1] to HSR[3] are in a low (L) state.

The selection pulse ϕSel_1 output from the vertical selection unit 4 to the pixel 3 of the first row transitions from the L state to the high (H) state and therefore the selection transistor Sel is turned on (a conductive state). Thereby, the pixel 3 of the first row is selected.

### (Reading of Reset Level)

The reset pulse ϕRst_1 output from the vertical selection unit 4 to the pixel 3 of the first row transitions from the L state to the H state and therefore the reset transistor Rst is turned on. Thereby, the charge storage portion FD is reset and a pixel signal 3 of the reset level is output to the vertical signal line 20. Thereafter, the reset pulse ϕRst_1 transitions from the H state to the L state and therefore the reset transistor Rst is turned off (a non-conductive state).

Thereafter, the sample-and-hold pulse ϕSHR transitions from the L state to the H state and therefore the sample transistor M2 is turned on. Thereafter, the sample-and-bold pulse ϕSHR transitions from the H state to the L state and therefore the sample transistor M2 is turned off. Thereby, the pixel signal of the reset level is held in the capacitive element Cr.

### (Reading of Signal Level)

The transfer pulse ϕTx_1 output from the vertical selection unit 4 to the pixel 3 of the first row transitions from the L state to the H state and therefore the transfer transistor Tx is turned on. Thereby, the signal charges of the photoelectric conversion unit PD are transferred to the charge storage portion FD and the pixel signal of the signal level is output to the vertical signal line 20. Thereafter, the transfer pulse ϕTx_1 transitions from the H state to the L state and therefore the transfer transistor Tx is turned off.

Thereafter, the sample-and-hold pulse ϕSHS transitions from the L state to the H state and therefore the sample transistor M3 is turned on. Thereafter, the sample-and-hold pulse ϕSHS transitions from the H state to the L state and therefore the sample transistor M3 is turned off. Thereby, the pixel signal of the signal level is held in the capacitive element Cs.

Thereafter, the selection pulse HSR[1] output from the horizontal selection unit 6 to the column circuit 8 of the first column transitions from the L state to the H state and therefore the column selection transistor M6 and the column selection transistor M7 are turned on. Thereby the first pixel signal according to the reset level of the pixel 3 in the first row and the first column is output to the horizontal signal line 21. At the same time, a second pixel signal according to the signal level of the pixel 3 in the first row and the first column is output to the horizontal signal line 22. Thereafter, the selection pulse HSR[1] transitions from the H state to the L state and therefore the column selection transistor M6 and the column selection transistor M7 are turned off. According to the above-described operation, the first pixel signal and the second pixel signal of the pixel 3 in the first row and the first column are read.

Thereafter, the selection pulse HSR[2] transitions from the L state to the H state. Thereby, as in the above-described operation, the first pixel signal and the second pixel signal of the pixel 3 in the first row and the second column are read. Thereafter, the selection pulse HSR[2] transitions from the H state to the L state and the selection pulse HSR[3] transitions from the L state to the H state. Thereby, as in the above-described operation, the first pixel signal and the second pixel signal of the pixel 3 in the first row and the third column are read. Thereafter, the selection pulse HSR[3] transitions from the H state to the L state.

Finally the selection pulse ϕSel_1 transitions from the H state to the L state and therefore the selection transistor Sel is turned off. Thereby, the selection of the pixel 3 of the first row is canceled and the operation of reading the pixel signal from the pixel 3 of the first row is completed. Following the operation shown in FIG. 7, an operation of reading the pixel signal from the pixel 3 of the second row is performed. This operation is similar to the operation shown in FIG. 7.

The imaging device of the second embodiment includes the AD conversion circuit the imaging unit 2, the column circuit 8, the current generation circuit 41 (a first current generation circuit), and the current generation circuit 42 (a second current generation circuit). The imaging unit 2 includes the plurality of pixels 3 disposed in a matrix shape. The column circuit 8 is electrically connected to the imaging unit 2 and generates a first pixel signal according to a reset level and a second pixel signal according to a signal level. The current generation circuit 41 is electrically connected to the column circuit 8 and generates a first pixel current signal according to the first pixel signal. The current generation circuit 42 is electrically connected to the column circuit 8 and generates a second pixel current signal according to the second pixel signal. The arithmetic circuit 12 is electrically connected to one of the current generation circuit 41 and the current generation circuit 42. The arithmetic circuit 12 is electrically connected to the second current generation circuit 42. The comparison circuit 13 is electrically connected to the other of the current generation circuit 41 and the current generation circuit 42. The comparison circuit 13 is electrically connected to the current generation circuit 41. The first current signal is one of the first pixel current signal and the second pixel current signal. The first current signal is the second current pixel signal. The second current signal is the other of the first pixel current signal and the second pixel current signal. The second current signal is the first pixel current signal.

The imaging device according to each aspect of the present invention need not have a configuration other than a configuration corresponding to each of the AD conversion circuit 10, the imaging unit 2, the column circuit 8, the current generation circuit 41, and the current generation circuit 42.

The imaging device 1 according to the second embodiment has a smaller AD conversion circuit 10. Therefore, it is possible to further reduce a size of the imaging device 1.

The current generation circuit 41 (a first current generation circuit) includes the transistor N1 (a first transistor) and the transistor N2 (a second transistor) constituting a current mirror circuit. The current generation circuit 42 (a second current generation circuit) includes the transistor N3 (a third transistor) and the transistor N4 (a fourth transistor) constituting a current mirror circuit. Thereby, the current generation circuit 41 and the current generation circuit 42 can easily amplify the signal.

### First Modified Example of Second Embodiment

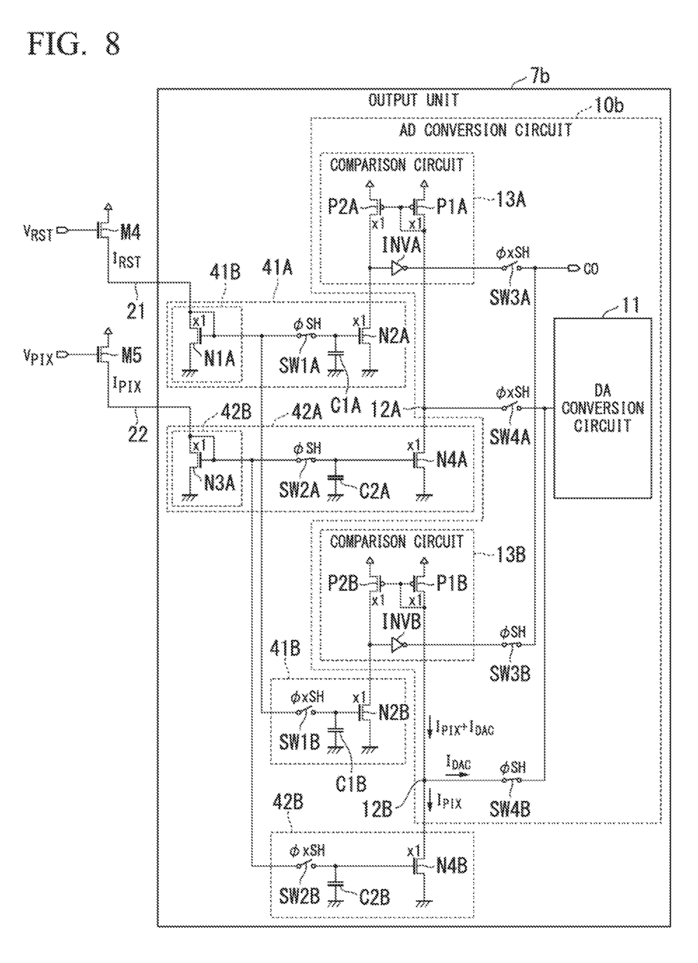

In the imaging device 1 according to a first modified example of the second embodiment of the present invention, the output unit 7 is changed to an output unit 7b shown in FIG. 8. FIG. 8 shows a configuration of the output unit 7b. As shown in FIG. 8, the output unit 7b includes an AD conversion circuit 10b, a current generation circuit 41A, a current generation circuit 41B, a current generation circuit 42A, and a current generation circuit 42B.

The AD conversion circuit 10b includes a DA conversion circuit 11, an arithmetic circuit 12A, an arithmetic circuit 12B, a comparison circuit 13A, a comparison circuit 13B, a switch SW3A, a switch SW3B, a switch SW4A, and a switch SW4B. The configuration of the DA conversion circuit 11 shown in FIG. 8 is the same as that of the DA conversion circuit 11 shown in FIG. 1. Thus, a detailed description of the configuration of the DA conversion circuit 11 will be omitted.

The arithmetic circuit 12A is connected to the current;generation circuit 42A. A second pixel current signal (a first current signal) generated by the current generation circuit 42A and a first reference current signal generated by the DA conversion circuit 11 are supplied to the arithmetic circuit 12A. The arithmetic circuit 12A generates a comparison current signal by adding the second pixel current signal to the first reference current signal.

The arithmetic circuit 12B is connected to the current generation circuit 42B. The second pixel current signal (the first current signal) generated by the current generation circuit 42B and the first reference current signal generated by the DA conversion circuit 11 are supplied to the arithmetic circuit 12B. The arithmetic circuit 12B generates a comparison current signal by adding the second pixel current signal to the first reference current signal.

The comparison circuit 13A includes a transistor P1A, a transistor P2A, and an inverter circuit INVA. The comparison circuit 13A includes a configuration similar to that of the comparison circuit 13 shown in FIG. 1. The transistor P1A corresponds to the transistor P1 shown in FIG. 1. The transistor P2A corresponds to the transistor P2 shown in FIG. 1. The inverter circuit INVA corresponds to an inverter circuit INV shown in FIG. 1. Thus, a detailed description of the configuration of the comparison circuit 13A will be omitted. The comparison circuit 13A is connected to the arithmetic circuit 12A and the current generation circuit 41A. The comparison current signal generated by the arithmetic circuit 12A and the first pixel current signal (the second current signal) generated by the current generation circuit 41A are supplied to the comparison circuit 13A. The comparison circuit 13A outputs digital data based on a result of comparing the first pixel current signal with the comparison current signal.

The comparison circuit 13B includes a transistor P1B, a transistor P2B, and an inverter circuit INVB. The comparison circuit 13B includes a configuration similar to that of the comparison circuit 13 shown in FIG. 1. The transistor P1B corresponds to the transistor P1 shown in FIG. 1. The transistor P2B corresponds to the transistor P2 shown in FIG. 1. The inverter circuit INVB corresponds to the inverter circuit INV shown in FIG. 1. Thus, a detailed description of the configuration of the comparison circuit 13B will be omitted. The comparison circuit 13B is connected to the arithmetic circuit 12B and the current generation circuit 41B. The comparison current signal generated by the arithmetic circuit 12B and the first pixel current signal (the second current signal) generated by the current generation circuit 41B are supplied to the comparison circuit 13B. The comparison circuit 13B outputs digital data based on a result of comparing the first pixel current signal with the comparison current signal.

The switch SW3A is connected to an output terminal of the inverter circuit INVA. The switch SW3A is an element capable of performing switching between ON and OFF. If the switch SW3A is turned on, the switch SW3A outputs the signal output from the output terminal of the inverter circuit INVA as a signal CO. The operation of the switch SW3A is controlled according to a control pulse ϕxSH,

The switch SW3B is connected to the output terminal of the inverter circuit INVB. The switch SW3B is an element capable of performing switching between ON and OFF. If the switch SW3B is turned on, the switch SW3B outputs the signal output from the output terminal of the inverter circuit INVB as a signal CO. The operation of the switch SW3B is controlled according to a control pulse ϕSH.

The switch SW4A is connected to the DA conversion circuit 11 and the arithmetic circuit 12A. The switch SW4A is an element capable of performing switching between ON and OFF. If the switch SW4A is turned on, the switch SW4A supplies the first reference current signal generated by the DA conversion circuit 11 to the arithmetic circuit 12A. The operation of the switch SW4A is controlled according to the control pulse ϕxSH.

The switch SW4B is connected to the DA conversion circuit 11 and the arithmetic circuit 12B. The switch SW4B is an element capable of performing switching between ON and OFF. If the switch SW4B is turned on, the switch SW4B supplies the first reference current signal generated by the DA conversion circuit 11 to the arithmetic circuit 12B. The operation of the switch SW4B is controlled according to the control pulse ϕSH.

When the control pulse ϕSH is in the H state, the control pulse ϕxSH is in the L state. At this time, the switches SW3B and SW4B are turned on and the switches SW3A and SW4A are turned off. Thus, the switch SW3B outputs the signal output from the output terminal of the inverter circuit INVB as a signal CO. When the control pulse ϕSH is in the L state, the control pulse ϕxSH is in the H state. At this time, the switches SW3A and SW4A are turned on and the switches SW3B and SW4B are turned off. Thus, the switch SW3A outputs the signal output from the output terminal of the inverter circuit INVA as the signal CO.

The current generation circuit 41A includes a transistor N1A, a transistor N2A, a sample switch SW1A, and a capacitive element C1A. The transistor N1A and the transistor N2A are configured to be similar to the transistor N1 and the transistor N2 shown in FIG. 6. The drain terminal of the transistor N1A is connected to the horizontal signal line 21. The source terminal of the transistor N1A is connected to the ground. The gate terminal of the transistor N1A is connected to the drain terminal of the transistor N1A. The drain terminal of the transistor N2 is connected to the drain terminal of the transistor P2A of the comparison circuit 13A. The source terminal of the transistor N2A is connected to the ground. The gate terminal of the transistor N2A is connected to the capacitive element C1A.

The sample switch SW1A is connected to the gate terminal of the transistor N1A and the capacitive element C1A. The sample switch SW1A is an element capable of performing switching between ON and OFF. If the sample switch SW1A is turned on, the sample switch SW1A samples the gate voltage of the transistor N1A. The sample switch SW1A transitions from ON to OFF and therefore the voltage sampled by the sample switch SW1A is held in the capacitive element C1A. The operation of the sample switch SW1A is controlled according to the control pulse ϕSH.

The current generation circuit 41B includes a transistor N1A, a transistor N2B, a sample switch SW1B, and a capacitive element C1B. The transistor N1A is commonly used in the current generation circuit 41A. The transistors N1A and N2B are configured to be similar to the transistors N1 and N2 shown in FIG. 6. The drain terminal of the transistor N2B is connected to the drain terminal of the transistor P2B of the comparison circuit 13B. The source terminal of the transistor N2B is connected to the ground. The gate terminal of the transistor N2B is connected to the capacitive element C1B.

The sample switch SW1B is connected to the gate terminal of the transistor N1A and the capacitive element C1B. The sample switch SW1B is an element capable of performing switching between ON and OFF. If the sample switch SW1B is turned on, the sample switch SW1B samples the gate voltage of the transistor N1A. The sample switch SW1B transitions from ON to OFF and therefore the voltage sampled by the sample switch SW1B is held in the capacitive element C1B. The operation of the sample switch SW1B is controlled according to the control pulse ϕxSH.

The current generation circuit 42A includes a transistor N3A, a transistor N4A, a sample switch SW2A, and a capacitive element C2A. The transistors N3A and N4A are configured to be similar to the transistors N3 and N4 shown in FIG. 6. The drain terminal of the transistor N3A is connected to the horizontal signal line 22. The source terminal of the transistor N3A is connected to the ground. The gate terminal of the transistor N3A is connected to the drain terminal of the transistor N3A. The drain terminal of the transistor N4A is connected to the arithmetic circuit 12A. The source terminal of the transistor N4A is connected to the ground. The gate terminal of the transistor N4A is connected to the capacitive element C2A.

The sample switch SW2A is connected to the gate terminal of the transistor N3A and the capacitive element C2A. The sample switch SW2A is an element capable of performing switching between ON and OFF. If the sample switch SW2A is turned on, the sample switch SW2A samples the gate voltage of the transistor N3A. The sample switch SW2A, transitions from ON to OFF and therefore the voltage sampled by the sample switch SW2A is held in the capacitive element C2A. The operation of the sample switch SW2A is controlled according to the control pulse ϕSH.

The current generation circuit 42B includes a transistor N3A, a transistor N4B, a sample switch SW2B, and a capacitive element C2B. The transistor N3A is commonly used in the current generation circuit 42A. The transistors N3A and N4B are configured to be similar to the transistors N3 and N4 shown in FIG. 6. The drain terminal of the transistor N4B is connected to the arithmetic circuit 12B. The source terminal of the transistor N4B is connected to the ground. The gate terminal of the transistor N4B is connected to the capacitive element C2B.

The sample switch SW2B is connected to the gate terminal of the transistor N3A and the capacitive element C2B. The sample switch SW2B is an element capable of performing switching between ON and OFF. If the sample switch SW2B is turned on, the sample switch SW2B samples the gate voltage of the transistor N3A. The sample switch SW2B transitions from ON to OFF and therefore the voltage sampled by the sample switch SW2B is held in the capacitive element C2B. The operation of the sample switch SW2B is controlled according to the control pulse ϕxSH.

When the control pulse ϕSH is in the H state, the control pulse ϕxSH is in the L state. At this time, the sample switch SW1A samples the gate voltage of the transistor N1A and the sample switch SW2A samples the gate voltage of the transistor N3A. On the other hand, the voltage sampled by the sample switch SW1B is held in the capacitive element C1B and the voltage sampled by the sample switch SW2B is held in the capacitive element C2B. The transistor N2B generates a first pixel current signal according to the voltage held in the capacitive element C1B. The transistor N4B generates a second pixel current signal according to the voltage held in the capacitive element C2B. The arithmetic circuit 12B generates a comparison current signal by adding the second pixel current signal to the first reference current signal. The inverter circuit INVB of the comparison circuit 13B compares the comparison current signal with the first pixel current signal and outputs a signal indicating the comparison result. The signal output from the inverter circuit INVB is output as the signal CO to the circuit of the subsequent stage. That is, the sampling operations of the current generation circuit 41A and the current generation circuit 42A and the comparison operation of the comparison circuit 13B are performed in parallel.

When the control pulse ϕSH is in the L state, the control pulse ϕxSH is in the H state. At this time, the sample switch SW1B samples the gate voltage of the transistor N1A and the sample switch SW2B samples the gate voltage of the transistor N3A. On the other hand, the voltage sampled by the sample switch SW1A is held in the capacitive element C1A and the voltage sampled by the sample switch SW2A is held in the capacitive element C2A. The transistor N2A generates a first pixel current signal according to the voltage held in the capacitive element C1A. The transistor N4A generates a second pixel current signal according to the voltage held in the capacitive element C2A. The arithmetic circuit 12A generates a comparison current signal by adding the second pixel current signal to the first reference current signal. The inverter circuit INVA of the comparison circuit 13A compares the comparison current signal with the first pixel current signal and outputs a signal indicating the comparison result. The signal output from the inverter circuit INVA is output as the signal CO to the circuit of the subsequent stage. That is, the sampling operations of the current generation circuit 41B and the current generation circuit 42B and the comparison operation of the comparison circuit 13A are performed in parallel.

As described above, the interleaved AD conversion circuit 10b can be configured. Thus, the AD conversion circuit 10b and the imaging device 1 can perform AD conversion at a higher speed.

### Second Modified Example of Second Embodiment

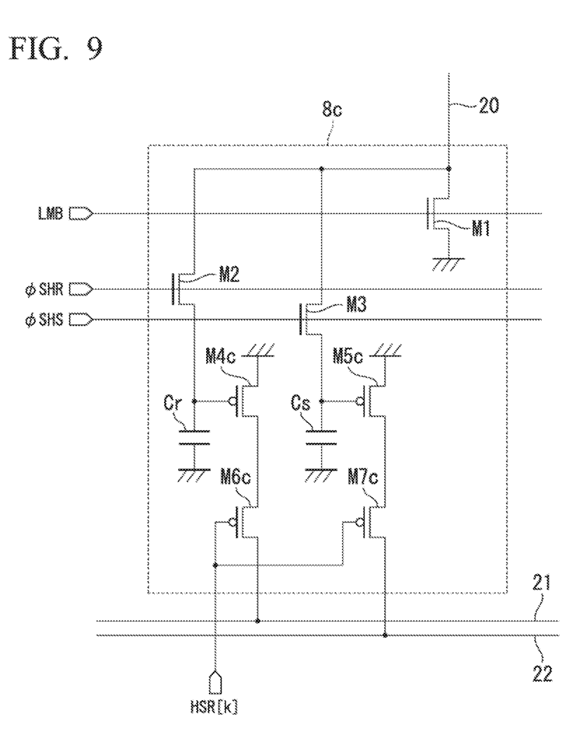

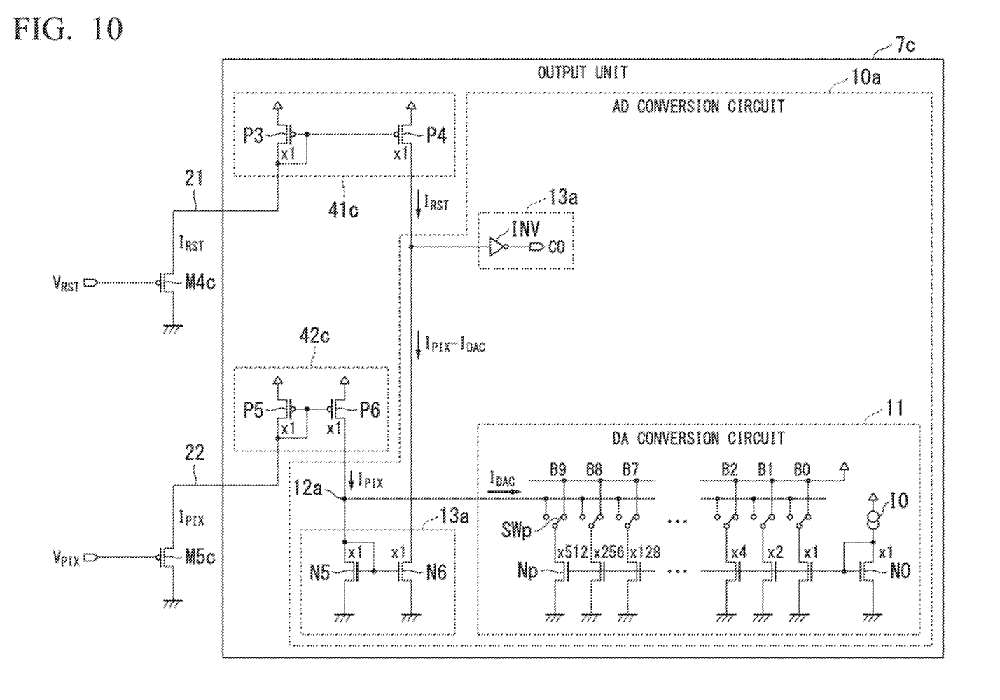

In an imaging device 1 of a second modified example of the second embodiment of the present invention, the column circuit 8 is changed to a column circuit 8c shown in FIG. 9 and the output unit 7 is changed to an output unit 7c shown in FIG. 10.

FIG. 9 shows a configuration of the column circuit 8c. With respect to the configuration shown in FIG. 9, differences from the configuration shown in FIG. 5 will be described. In the column circuit 8c, the amplification transistor M4 in the column circuit 8 shown in FIG. 5 is changed to an amplification transistor M4c, and the amplification transistor M5 in the column circuit 8 shown in FIG. 5 is changed to an amplification transistor M5c. In the column circuit 8c, the column selection transistor M6 in the column circuit 8 shown in FIG. 5 is changed to a column selection transistor M6c and the column selection transistor M7 in the column circuit 8 shown in FIG. 5 is changed to a column selection transistor M7c. The amplification transistor M4c, the amplification transistor M5c, the column selection transistor M6c, and the column selection transistor M7c are PMOS transistors. Each of the amplification transistor M4c, the amplification transistor M5c, the column selection transistor M6c, and the column selection transistor M7c includes a gate terminal, a source terminal, and a drain terminal.

The drain terminal of the amplification transistor M4c is connected to the ground. The source terminal of the amplification transistor M4c is connected to the column selection transistor M6c. The gate terminal of the amplification transistor M4c is connected to a first terminal of a capacitive element Cr.

The drain terminal of the amplification transistor M5c is connected to the around. The source terminal of the amplification transistor M5c is connected to the column selection transistor M7c. The gate terminal of the amplification transistor M5c is connected to a first terminal of a capacitive element Cs.

The drain terminal of the column selection transistor M6c is connected to the source terminal of the amplification transistor M4c. The source terminal of the column selection transistor M6c is connected to a horizontal signal line 21. The gate terminal of the column selection transistor M6c is connected to a horizontal selection unit 6.

The drain terminal of the column selection transistor M7c is connected to the source terminal of the amplification transistor M5c. The source terminal of the column selection transistor M7c is connected to a horizontal signal line 22. The gate terminal of the column selection transistor M7c is connected to the horizontal selection unit 6.

The column selection transistor M6c and the column selection transistor M7c are controlled according to a selection pulse HSR[k] output from the horizontal selection unit 6. k is any one of 1, 2, and 3.

The amplification transistor M4c generates a first pixel signal by amplifying a pixel signal of a reset level held in the capacitive element Cr. That is, the amplification transistor M4c generates the first pixel signal based on the pixel signal of the reset level. The amplification transistor M5c generates a second pixel signal by amplifying a pixel signal of a signal level held in the capacitive element Cs. That is, the amplification transistor M5c generates the second pixel signal based on the pixel signal of the signal level. The column selection transistor M6c outputs the first pixel signal generated by the amplification transistor M4c to the horizontal signal line 21. The column selection transistor M7c outputs the second pixel signal generated by the amplification transistor M5c to the horizontal signal line 22. The column selection transistor M6c and the column selection transistor M7c of the first column are controlled according to a selection pulse HSR[1]. The column selection transistor M6c and the column selection transistor M7c of the second column are controlled according to a selection pulse HSR[2]. The column selection transistor M6c and the column selection transistor M7c of the third column are controlled according to a selection pulse HSR[3].

In terms of details other than the above, the configuration shown in FIG. 9 is similar to the configuration shown in FIG. 5.

FIG. 10 shows a configuration of an output unit 7c. As shown in FIG. 10, the output unit 7c includes an AD conversion circuit 10a, a current generation circuit 41c, and a current generation circuit 42c. A configuration of the AD conversion circuit 10a shown in FIG. 10 is the same as that of the AD conversion circuit 10a shown in FIG. 2. Thus, a detailed description of the configuration of the AD conversion circuit 10a will be omitted.

The current generation circuit 41c includes a transistor P3 and a transistor P4. The transistor P3 and the transistor P4 are PMOS transistors. Each of the transistor P3 and the transistor P4 includes a gate terminal, a source terminal, and a drain terminal. The drain terminal of the transistor P3 is connected to the horizontal signal line 21. The source terminal of the transistor P3 is connected to a power supply configured to supply a power-supply voltage. The gate terminal of the transistor P3 is connected to the drain terminal of the transistor P3. The drain terminal of the transistor P4 is connected to the drain terminal of the transistor N6 of the comparison circuit 13a. The source terminal of the transistor P4 is connected to a power supply configured to supply a power-supply voltage. The gate terminal of the transistor P4 is connected to the gate terminal of the transistor P3.

The horizontal signal line 21 is connected to the column circuit 8c. Thus, the current generation circuit 41c is electrically connected to the column circuit 8c via the horizontal signal line 21.

The first pixel signal output from the amplification transistor M4c of the column circuit 8c to the horizontal signal line 21 via the column selection transistor M6c is input to the current generation circuit 41c. In FIG. 10, the column selection transistor M6c is not shown. The first pixel signal is based on the pixel signal of a reset level (V_{RST}). The current value of the first pixel signal is I_{RST}. The first pixel signal flows between the source terminal of the transistor P3 and the drain terminal of the transistor P3. The transistor P3 and the transistor P4 constitute a current mirror circuit. A current corresponding to a mirror ratio of the transistor P3 and the transistor P4 flows between the source terminal of the transistor P4 and the dram terminal of the transistor P4. In FIG. 10, an example in which the mirror ratio of the transistor P3 and the transistor P4 is 1:1 is shown. The transistor P4 generates the first pixel current signal by returning the first pixel signal flowing through the transistor P3 in accordance with the mirror ratio of the transistor P3 and the transistor P4. In this example, a current whose current value is the same as the current value (I_{RST}) of the first pixel signal flows between the source terminal of the transistor P4 and the drain terminal of the transistor P4. The mirror ratio of the transistor P3 and the transistor P4 is not limited to 1:1. By changing the mirror ratio of the transistor P3 and the transistor P4, the current generation circuit 41c can have a signal amplification function.

The first pixel current signal generated by the transistor P4 is supplied to the comparison circuit 13a. According to the above-described configuration, the current generation circuit 41c generates the first pixel current signal according to the first pixel signal.

The current generation circuit 42c includes a transistor P5 and a transistor P6. The transistor P5 and the transistor P6 are PMOS transistors. Each of the transistor P5 and the transistor P6 includes a gate terminal, a source terminal, and a drain terminal. The drain terminal of the transistor P5 is connected to the horizontal signal line 22. The source terminal of the transistor P5 is connected to a power supply configured to supply a power-supply voltage. The gate terminal of the transistor P5 is connected to the drain terminal of the transistor P5. The drain terminal of the transistor P6 is connected to the arithmetic circuit 12a. The source terminal of the transistor P6 is connected to a power supply configured to supply a power-supply voltage. The gate terminal of the transistor P6 is connected to the gate terminal of the transistor P5.

The horizontal signal line 22 is connected to the column circuit 8c. Thus, the current generation circuit 42c is electrically connected to the column circuit 8c via the horizontal signal line 22.

The second pixel signal output from the amplification transistor M5c of the column circuit 8c to the horizontal signal line 22 via the column selection transistor M7c is input to the current generation circuit 42c. In FIG. 10, the column selection transistor M7c is not shown. The second pixel signal is based on the pixel signal of the signal level (V_{PIX}). The current value of the second pixel signal is I_{PIX}. In the description of this modified example, the current value (I_{RST}) of the first pixel signal is assumed to be smaller than the current value (I_{PIX}) of the second pixel signal. The second pixel signal flows between the source terminal of the transistor P5 and the drain terminal of the transistor P5. The transistor P5 and the transistor P6 constitute a current mirror circuit. A current corresponding to a mirror ratio of the transistor P5 and the transistor P6 flows between the source terminal of the transistor P6 and the drain terminal of the transistor P6. In FIG. 10, an example in which the mirror ratio of the transistor P5 and the transistor P6 is 1:1 is shown. The transistor P6 generates the second pixel current signal by returning the second pixel signal flowing through the transistor P5 in accordance with the mirror ratio of the transistor P5 and the transistor P6. In this example, a current whose current value is the same as the current value (I_{PIX}) of the second pixel signal flows between the source terminal of the transistor P6 and the drain terminal of the transistor P5. The mirror ratio of the transistor P5 and the transistor P6 is not limited to 1:1. By changing the mirror ratio of the transistor P5 and the transistor P6, the current generation circuit 42c can have a signal amplification function.

The second pixel current signal generated by the transistor P6 is supplied to the arithmetic circuit 12a. According to the above-described configuration, the current generation circuit 42c generates the second pixel current signal according to the second pixel signal.

If the mirror ratio of the transistor N5 and the transistor N6 is 1:1, the comparison circuit 13a outputs a signal CO according to a difference between the first pixel current signal generated by the transistor P4 and the second pixel current signal generated by the transistor P6. That is, the AD conversion circuit 10a can perform AD conversion on the difference between the first pixel current signal and the second pixel current signal. In addition, if the mirror ratio of the transistor P3 and the transistor P4 is the same as the mirror ratio of the transistor P5 and the transistor P6, the AD conversion circuit 10a can perform AD conversion on the difference between the first pixel signal and the second pixel signal.

At least one of the current generation circuit 41c and the current generation circuit 42c may be disposed on the substrate constituting the AD conversion circuit 10a. That is, the AD conversion circuit 10a may include at least one of the current generation circuit 41c and the current generation circuit 42c.

In the AD conversion circuit 10a, the arithmetic circuit 12a is electrically connected to the current generation circuit 42c. The comparison circuit 13a is electrically connected to the current generation circuit 41c. The second pixel current signal generated by the current generation circuit 42c is supplied as a first current signal to the arithmetic circuit 12a. The first pixel current signal generated by the current generation circuit 41c is supplied as a second current signal to the comparison circuit 13a.

The arithmetic circuit 12a generates a comparison current signal by subtracting the first reference current signal (I_{DAC}) from the first current signal (I_{PIX}). The comparison circuit 13a outputs digital data based on a result of comparing the second current signal (I_{RST}) with the comparison current signal.

The imaging device 1 according to the second modified example of the second embodiment has a smaller AD conversion circuit 10a. Therefore, it is possible to further reduce a size of the imaging device 1.

The current generation circuit 41c (a first current generation circuit) includes the transistor P3 (a first transistor) and the transistor P4 (a second transistor) constituting a current mirror circuit. The current generation circuit 42c (a second current generation circuit) has the transistor P5 (a third transistor) and the transistor P6 (fourth transistor) constituting a current mirror circuit. Thereby, the current generation circuit 41c and the current generation circuit 42c can easily amplify the signal.

### Third Modified Example of Second Embodiment

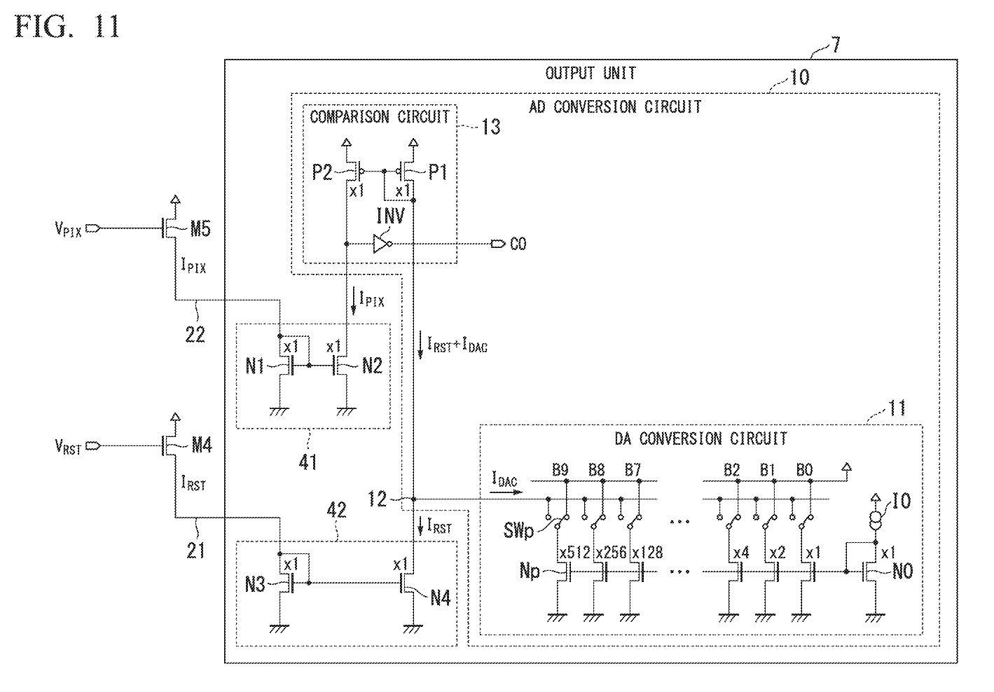

FIG. 11 shows a configuration of an output unit 7 of an imaging device 1 according to a third modified example of the second embodiment of the present invention. The configuration of the output unit 7 shown in FIG. 11 is the same as that of the output unit 7 shown in FIG. 6. Thus, a detailed description of the configuration of the output unit 7 will be omitted.

Connections of the current generation circuit 41 and the current generation circuit 42 to the horizontal signal line 21 and the horizontal signal line 22 are different from those shown in FIG. 6. A drain terminal of a transistor N1 is connected to the horizontal signal line 22, and a drain terminal of a transistor N3 is connected to the horizontal signal line 21.

A first pixel signal output from an amplification transistor M4 of a column circuit 8 to the horizontal signal line 21 via a column selection transistor M6 is input to a current generation circuit 42. In FIG. 11, the column selection transistor M6 is not shown. The first pixel signal is based on a pixel signal of a reset level (V_{RST}). The current value of the first pixel signal is I_{RST}. The first pixel signal flows between the drain terminal of the transistor N3 and the source terminal of the transistor N3. The transistor N4 generates a first pixel current signal by returning the first pixel signal flowing through the transistor N3 in accordance with a mirror ratio of the transistor N3 and the transistor N4. In this example, a current whose current value is the same as the current value (I_{RST}) of the first pixel signal flows between the drain terminal of the transistor N4 and the source terminal of the transistor N4. The first pixel current signal generated by the transistor N4 is supplied as a first current signal to the arithmetic circuit 12.

A second pixel signal output from the amplification transistor M5 of the column circuit 8 to the horizontal signal line 22 via a column selection transistor M7 is input to a current generation circuit 41. In FIG. 11, the column selection transistor M7 is not shown. The second pixel signal is based on a pixel signal of a signal level (V_{PIX}). The current value of the second pixel signal is I_{PIX}. In the description of this modified example, the current value (I_{RST}) of the first pixel signal is assumed to be smaller than the current value (I_{PIX}) of the second pixel signal. The second pixel signal flows between the drain terminal of the transistor N1 and the source terminal of the transistor N1. The transistor N2 generates a second pixel current signal by returning the second pixel signal flowing through the transistor N1 in accordance with a mirror ratio of the transistor N1 and the transistor N2. In this example, a current whose current value is the same as the current value (I_{PIX}) of the second pixel signal flows between the drain terminal of the transistor N2 and the source terminal of the transistor N2. The second pixel current signal generated by the transistor N2 is supplied as a second current signal to the comparison circuit 13.

An operation of the AD conversion circuit 10 is similar to the operation of the AD conversion circuit 10 shown in FIG. 1. Thus, a detailed description of the operation of the AD conversion circuit 10 will be omitted.

Instead of the output unit 7, the output unit 7c shown in FIG. 10 may be used.

In the imaging device 1 according to the third modified example of the second embodiment, the current generation circuit 42 (a first current generation circuit) is electrically connected to the column circuit 8 and generates a first pixel current signal according to a first pixel signal. The current generation circuit 41 (a second current generation circuit) is electrically connected to the column circuit 8 and generates a second pixel current signal according to a second pixel signal. The arithmetic circuit 12 is electrically connected to one of the current generation circuit 41 and the current generation circuit 42. The arithmetic circuit 12 is electrically connected to the current generation circuit 42. The comparison circuit 13 is electrically connected to the other of the current generation circuit 41 and the current generation circuit 42. The comparison circuit 13 is electrically connected to the current generation circuit 41. The first current signal is one of the first pixel current signal and the second pixel current signal. The first current signal is the first pixel current signal. The second current signal is the other of the first pixel current signal and the second pixel current signal. The second current signal is the second pixel current signal.

The imaging device 1 of the third modified example of the second embodiment has a smaller AD conversion circuit 10. Therefore, it is possible to further reduce a size of the imaging device 1.

### Third Embodiment

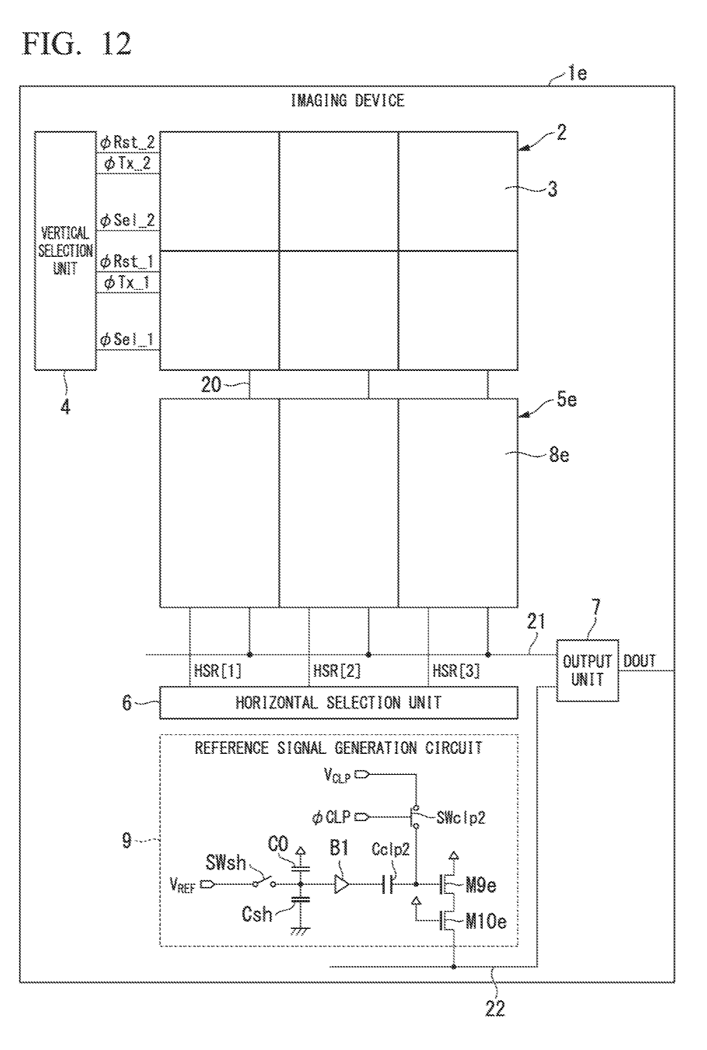

FIG. 12 shows a configuration of an imaging device 1e according to a third embodiment of the present invention. The configuration shown in FIG. 12 will be described in terms of differences from the configuration shown in FIG. 3.

As shown in FIG. 12, the imaging device 1e includes an imaging unit 2, a vertical selection unit 4, a column circuit unit 5e, a horizontal selection unit 6, an output unit 7, and a reference signal generation circuit 9. For example, the imaging unit 2, the vertical selection unit 4, the column circuit unit 5e, the horizontal selection unit 6, the output unit 7, and the reference signal generation circuit 9 are disposed on the same substrate. If a chip on which the imaging device 1e is disposed includes a plurality of substrates, the imaging unit 2, the vertical selection unit 4, the column circuit unit 5e, the horizontal selection unit 6, the output unit 7, and the reference signal generation circuit 9 may be distributed to the plurality of substrates.

In the imaging device 1e, the column circuit unit 5 in the imaging device 1 shown in FIG. 3 is changed to a column circuit unit 5e. In the column circuit unit 5e, the column circuit 8 in the column circuit unit 5 shown in FIG. 3 is changed to a column circuit 8e. The column circuit unit 5e includes a plurality of column circuits 8e. The column circuit 8e is disposed for each column in an array of a plurality of pixels 3. The column circuit 8e is connected to a vertical signal line 20. The column circuit 8e is electrically connected to the pixel 3 via the vertical signal line 20. The column circuit 8e generates a difference signal according to a difference between a reset level and a signal level output from the pixel 3. The column circuit 8e is connected to a horizontal signal line 21. A selection pulse HSR[k] from the horizontal selection unit 6 is output to the column circuit 8e corresponding to a column k. k is any one of 1, 2, and 3. The column circuit 8e selected according to the selection pulse HSR[k] outputs the difference signal to the horizontal signal line 21.

The reference signal generation circuit 9 includes a sample switch SWsh, a capacitive element C0, a capacitive element Csh, a buffer B1, a capacitive element Cclp2, a clamp switch SWclp2, an amplification transistor M9e, and a selective transistor M10e.

The sample switch SWsh includes a first terminal and a second terminal. The first terminal of the sample switch SWsh is connected to a power supply configured to output a reference voltage. The voltage value of the reference voltage is V_{REF}. The reference voltage is generated on the basis of the power-supply voltage. The second terminal of the sample switch SWsh is connected to the capacitive element C0 and the capacitive element Csh.

The capacitive element C0 and the capacitive element Csh include a first terminal and a second terminal. The first terminals of the capacitive element C0 and the capacitive element Csh are connected to the second terminal of the sample switch SWsh. The second terminal of the capacitive element C0 is connected to a power supply configured to output a power-supply voltage. The second terminal of the capacitive element Csh is connected to the ground.

The buffer B1 includes a first terminal and a second terminal. The first terminal of the buffer B1 is connected to the second terminal of the sample switch SWsh. The second terminal of the buffer B1 is connected to the capacitive element Cclp2.

The capacitive element Cclp2 includes a first terminal and a second terminal. The first terminal of the capacitive element Cclp2 is connected to the second terminal of the buffer B1. The second terminal of the capacitive element Cclp2 is connected to the clamp switch SWclp2 and the amplification transistor M9e.

The clamp switch SWclp2 includes a first terminal and a second terminal. The first terminal of the clamp switch SWclp2 is connected to the second terminal of the capacitive element Cclp2. The second terminal of the clamp switch SWclp2 is connected to a power supply configured to output a clamp voltage. The voltage value of the clamp voltage is V_{CLP}.

The amplification transistor M9e and the selection transistor M10e are NMOS transistors. Each of the amplification transistor M9e and the selection transistor M10e includes a gate terminal, a source terminal, and a drain terminal. The drain terminal of the amplification transistor M9e is connected to a power supply configured to output the power-supply voltage. The source terminal of the amplification transistor M9e is connected to the selection transistor M10e. The gate terminal of the amplification transistor M9e is connected to the second terminal of the capacitive element Cclp2.

The drain terminal of the selection transistor M10e is connected to the source terminal of the amplification transistor M9e. The source terminal of the selection transistor M10e is connected to the horizontal signal line 22. The gate terminal of the selection transistor M10e is connected to a power supply configured to output a power-supply voltage.

The sample switch SWsh is an element capable of performing switching between ON and OFF. If the sample switch SWsh is turned on, the sample switch SWsh samples the reference voltage. The sample switch SWsh transitions from ON to OFF and therefore the reference voltage sampled by the sample switch SWsh is held in the capacitive element Cclp2 via the buffer B1.

The clamp switch SWclp2 is an element capable of performing switching between ON and OFF. If the clamp switch SWclp2 is turned on, the capacitive element Cclp2 is clamped to the clamp voltage. The operation of the clamp switch SWclp2 is controlled according to a clamp pulse ϕCLP.

The capacitive element Cclp2 holds the voltage (V_{CLP}) clamped by the clamp switch SWclp2. The capacitive element Cclp2 is a clamp capacitor. If the power-supply voltage has changed, a voltage component due to the change is transmitted to the amplification transistor M9e via the capacitive element Cclp2. The amplification transistor M9e generates a reference signal by amplifying the voltage of the second terminal of the capacitive element Cclp2. That is, the amplification transistor M9e generates the reference signal based on the voltage of the first terminal of the capacitive element Cclp2 and the voltage of the second terminal of the capacitive element Cclp2. The selection transistor M10e outputs the reference signal generated by the amplification transistor M9e to the horizontal signal line 22. The reference signal includes a voltage component based on a change in the power-supply voltage.

In terms of details other than the above, the configuration shown in FIG. 12 is similar to the configuration shown in FIG. 3.

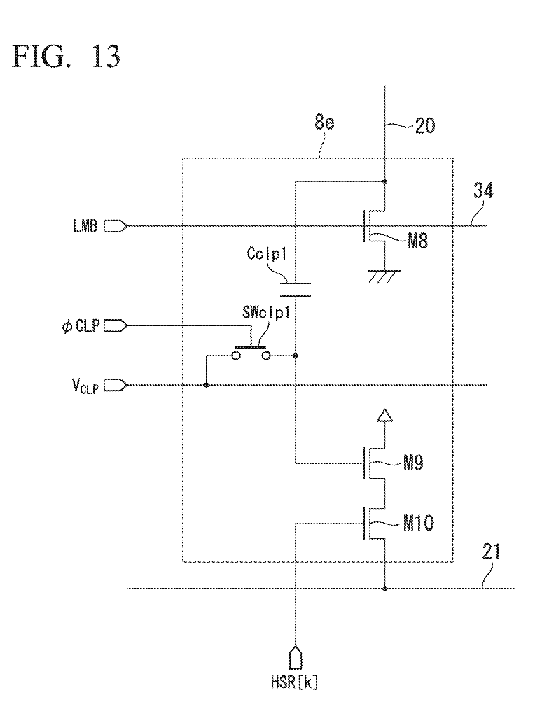

FIG. 13 shows a configuration of the column circuit 8e. As shown in FIG. 13, the column circuit 8e includes a transistor M8, a capacitive element Cclp1, a clamp switch SWclp1, an amplification transistor M9, and a column selection transistor M10. Each transistor shown in FIG. 13 is an NMOS transistor. Each transistor shown in FIG. 13 includes a gate terminal, a source terminal, and a drain terminal.

The drain terminal of the transistor M8 is connected to the vertical signal line 20. The source terminal of the transistor M8 is connected to the ground. The gate terminal of the transistor M8 is connected to the power supply line 34. The power supply line 34 is connected to a power supply configured to output a predetermined voltage LMB.

The capacitive element Cclp1 includes a first terminal and a second terminal. The first terminal of the capacitive element Cclp1 is connected to the vertical signal line 20. The second terminal of the capacitive element Cclp1 is connected to the clamp switch SWclp1 and the amplification transistor M9.

The clamp switch SWclp1 includes a first terminal and a second terminal. The first terminal of the clamp switch SWclp1 is connected to the second terminal of the capacitive element Cclp1. The second terminal of the clamp switch SWclp1 is connected to a power supply configured to output a clamp voltage. The voltage value of the clamp voltage is V_{CLP}.

The drain terminal of the amplification transistor M9 is connected to a power supply configured to output a power-supply voltage. The source terminal of the amplification transistor M9 is connected to the column selection transistor M10. The gate terminal of the amplification transistor M9 is connected to the second terminal of the capacitive element Cclp1.

The drain terminal of the column selection transistor M10 is connected to the source terminal of the amplification transistor M9. The source terminal of the column selection transistor M10 is connected to the horizontal signal line 21. The gate terminal of the column selection transistor M10 is connected to the horizontal selection unit 6.

The operation of the clamp switch SWclp1 is controlled according to the clamp pulse ϕCLP. The column selection transistor M10 is controlled according to a selection pulse HSR[k] output from the horizontal selection unit 6. k is any one of 1, 2, and 3.

The transistor M8 functions as a current source. The clamp switch SWclp1 is an element capable of performing switching between ON and OFF. If the clamp switch SWclp1 is turned on, the capacitive element Cclp1 is clamped to the clamp voltage. The operation of the clamp switch SWclp1 is controlled according to the clamp pulse ϕCLP. After the capacitive element Cclp1 is clamped, the capacitive element Cclp1 holds the pixel signal according to a difference between a reset level and a signal level output from the pixel 3 to the vertical signal line 20. The capacitive element Cclp1 is a clamp capacitor. The amplification transistor M9 amplifies the pixel signal held in the capacitive element Cclp1 and therefore generates a difference signal according to the difference between the reset level and the signal level. The column selection transistor M10 outputs the difference signal generated by the amplification transistor M9 to the horizontal signal line 21. The column selection transistor M10 of the first column is controlled according to a selection pulse HSR[1]. The column selection transistor M10 of the second column is controlled according to a selection pulse HSR[2]. The column selection transistor M10 of the third column is controlled according to a selection pulse HSR[3].

The capacitive element Cclp1, the clamp switch SWclp1, the amplification transistor M9, and the column selection transistor M10 in the column circuit 8e are configured to be similar to the capacitive element Cclp2, the clamp switch SWclp2, the amplification transistor M9e, and the selection transistor M10e in the reference signal generation circuit 9.

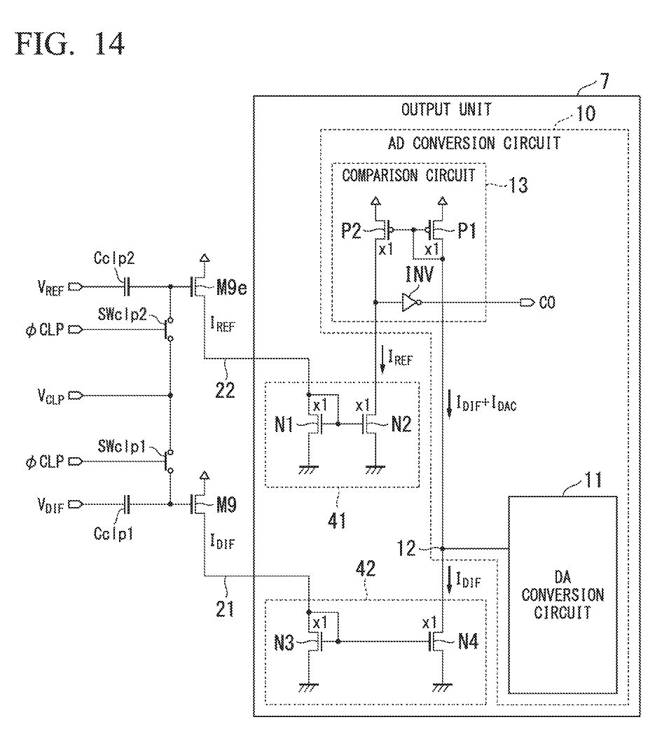

FIG. 14 shows the configuration of the output unit 7. The configuration of the output unit 7 shown in FIG. 14 is the same as that of the output unit 7 shown in FIG. 6. Thus, a detailed description of the configuration of the output unit 7 will be omitted.

Connections of the current generation circuit 41 and the current generation circuit 42 to the horizontal signal line 21 and the horizontal signal line 22 are different from those shown in FIG. 6. The drain terminal of the transistor N1 is connected to the horizontal signal line 22 and the drain terminal of the transistor N3 is connected to the horizontal signal line 21. The current generation circuit 41 is electrically connected to the reference signal generation circuit 9 via the horizontal signal line 22. The current generation circuit 42 is electrically connected to the column circuit 8e via the horizontal signal line 21.

The difference signal output from the amplification transistor M9 of the column circuit 8e to the horizontal signal line 21 via the column selection transistor M10 is input to the current generation circuit 42. In FIG. 14, the column selection transistor M10 is not shown. The difference signal is based on a difference (V_{DIF}) between the reset level and the signal level. The current value of the difference signal is I_{DIF}. The difference signal flows between the drain terminal of the transistor N3 and the source terminal of the transistor N3. The transistor N4 generates a difference current signal by returning the difference signal flowing through the transistor N3 in accordance with a mirror ratio of the transistor N3 and the transistor N4. In this example, a current whose current value is the same as the current value (I_{DIF}) of the difference signal flows between the drain terminal of the transistor N4 and the source terminal of the transistor N4. The difference current signal generated by the transistor N4 is supplied as a first current signal to the arithmetic circuit 12.

The reference signal output from the amplification transistor M9e of the reference signal generation circuit 9 to the horizontal signal line 22 via the selection transistor M10e is input to the current generation circuit 41. In FIG. 14, the selection transistor M10e is not shown. The reference signal is based on the voltage (V_{REF}) of the first terminal of the capacitive element Cclp2 and the voltage (V_{CLP}) of the second terminal of the capacitive element Cclp2. The current value of the reference signal is I_{REF}. In the description of the third embodiment, the current value (I_{DIF}) of the difference signal is assumed to be smaller than the current value (I_{REF}) of the reference signal. The reference signal flows between the drain terminal of the transistor N1 and the source terminal of the transistor N1. The transistor N2 generates a second reference current signal by returning the reference signal flowing through the transistor N1 in accordance with a mirror ratio of the transistor N1 and the transistor N2. In this example, a current whose current value is the same as the current value (I_{REF}) of the reference signal flows between the drain terminal of the transistor N2 and the source terminal of the transistor N2. The second reference current signal generated by the transistor N2 is supplied as a second current signal to the comparison circuit 13.

The operation of the AD conversion circuit 10 shown in FIG. 14 is similar to the operation of the AD conversion circuit 10 shown in FIG. 1. Thus, a detailed description of the operation of the AD conversion circuit 10 shown in FIG. 14 will be omitted.

If the power-supply voltage has changed, a change component (ΔV_{CLP}) of the voltage of the second terminal of the capacitive element Cclp2 is represented by Equation (1). In Equation (1), C₀ is a capacitance value of the capacitive element C0 and C_{SH} is a capacitance value of the capacitive element Csh. ΔV_{DD} is a component corresponding to a change in the power-supply voltage.

$$Δ {V}_{CLP} = \frac{{C}_{0}}{{C}_{0} + {C}_{SH}} \times Δ {V}_{DD} \qquad ( 1 )$$

If the power-supply voltage has changed, the reference signal generated by the amplification transistor M9e of the reference signal generation circuit 9 includes a component based on the above-described change component (ΔV_{CLP}). On the other hand, if the power-supply voltage has changed, the difference signal generated by the amplification transistor M9 of the column circuit 8e includes a component based on the component according to the change in the power-supply voltage. The AD conversion circuit 10 generates digital data according to the difference between the current value (I_{DIF}) of the first current signal according to the difference signal and the current value (I_{REF}) of the second current signal according to the reference signal and therefore the component according to the change in the power-supply voltage is reduced.

The capacitive element C0 of the reference signal generation circuit 9 corresponds to a first parasitic capacitor between the charge storage portion FD of the pixel 3 and the power supply. The capacitive element Csh of the reference signal generation circuit 9 corresponds to a second parasitic capacitor between the charge storage portion FD of the pixel 3 and the ground. If a ratio between the capacitance value of the capacitive element C0 and the capacitance value of the capacitive element Csh is equal to a ratio between the capacitance value of the first parasitic capacitor and the capacitance value of the second parasitic capacitor, a change component included in the reference signal is substantially the same as the change component included in the difference signal. In this case, the change component in the digital data is almost canceled.

The configuration of the reference signal generation circuit 9 is not limited to the configuration shown in FIG. 12. Another configuration capable of reducing the component according to the change in the power-supply voltage may be applied to the reference signal generation circuit 9. If it is unnecessary to consider an influence due to a change in the power-supply voltage, a configuration capable of generating any reference signal may be applied to the reference signal generation circuit 9. It is only necessary for the current value of the reference signal generated by the reference signal generation circuit 9 to be any value for inverting the signal CO output from the inverter circuit INV in accordance with the increase or decrease in the current value (I_{DAC}) of the first reference current signal in the AD conversion circuit 10.

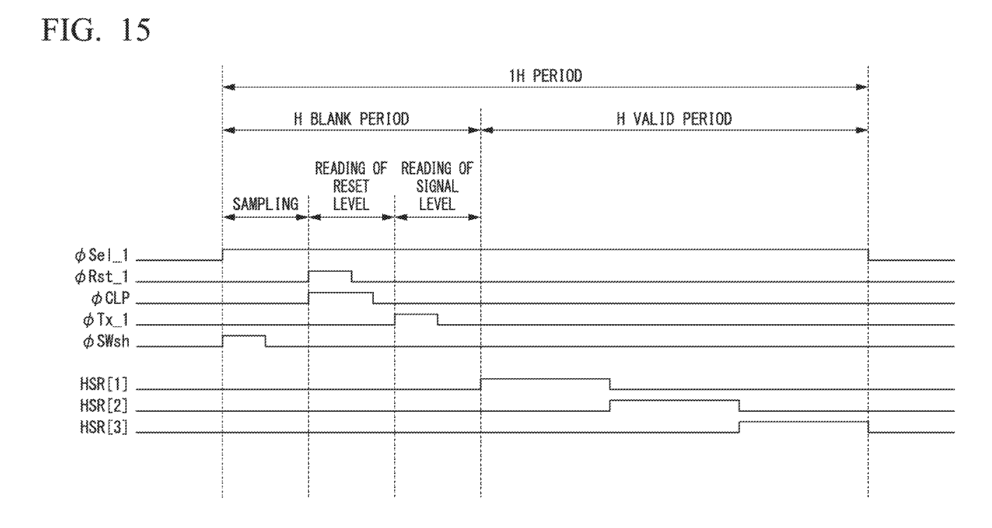

An operation of the imaging device 1e will be described. FIG. 15 shows the operation of the imaging device 1e. Hereinafter, an operation of reading the pixel signal in the imaging device 1e will be described. As a representative, an operation of reading a pixel signal from the pixel 3 of the first row in the array of the plurality of pixels 3 will be described.

In FIG. 15, waveforms of the selection pulse ϕSel_1, the reset pulse ϕRst_1, the transfer pulse ϕTx_1, the selection pulses HSR[1] to HSR[3], and the sample-and-hold pulse ϕSWsh are shown. The sample-and-hold pulse ϕSWsh is a signal for controlling the sample switch SWsh of the reference signal generation circuit 9. In FIG. 15, the horizontal direction represents time and the vertical direction represents voltage.

Before the reading operation of the pixel signal is started, the selection pulse ϕSel_1, the reset pulse ϕRst_1, the clamp pulse ϕCLP, the transfer pulse ϕTx_1, the sample-and-hold pulse ϕSWsh, and the selection pulses HSR[1] to HSR[3] are in the L state.

The selection pulse ϕSel_1 output from the vertical selection unit 4 to the pixel 3 of the first row transitions from the L state to the H state and therefore the selection transistor Sel is turned on. Thereby, the pixel 3 of the first row is selected. At the same time, the sample-and-hold pulse ϕSWsh transitions from the L state to the H state and therefore the sample switch SWsh is turned on. Thereafter, the sample-and-hold pulse ϕSWsh transitions from the H state to the L state and therefore the sample switch SWsh is turned off. Thereby, the reference voltage sampled by the sample switch SWsh is held in the capacitive element Cclp2 via the buffer B1.

### (Reading of Reset Level)

When the reset pulse ϕRst_1 output from the vertical selection unit 4 to the pixel 3 of the first row transitions from the L state to the H state, the reset transistor Rst is turned on. Thereby, the charge storage portion FD is reset and a pixel signal of the reset level is output to the vertical signal line 20. Furthermore, the clamp pulse ϕCLP transitions from the L state to the H state and the clamp switch SWclp1 and the clamp switch SWclp2 are turned on. Thereby, the capacitive element Cclp1 and the capacitive element Cclp2 are clamped to a clamp voltage. Thereafter, the reset pulse ϕRst_1 transitions from the H state to the L state and therefore the reset transistor Rst is turned off. Thereafter, the clamp pulse ϕCLP transitions from the H state to the L state and therefore the clamp switch SWclp1 and the clamp switch SWclp2 are turned off. Thereby, the clamp voltage is held in the capacitive element Cclp1 and the capacitive element Cclp2.

### (Reading of Signal Level)

The transfer pulse ϕTx_1 output from the vertical selection unit 4 to the pixel 3 of the first row transitions from the L state to the H state and therefore the transfer transistor Tx is turned on. Therefore, the signal charges of the photoelectric conversion unit PD are transferred to the charge storage portion FD and the pixel signal of the signal level is output to the vertical signal line 20. Thereafter, the transfer pulse ϕTx transitions from the H state to the L state and therefore the transfer transistor Tx is turned off. Thereby the pixel signal according to the difference between the reset level and the signal level is held in the capacitive element Cclp1.

Thereafter, the selection pulse HSR[1] output from the horizontal selection unit 6 to the column circuit 8e of the first column transitions from the L state to the H state and therefore the column selection transistor M10 is turned on. Thereby, a difference signal according to the difference between the reset level and the signal level of the pixel 3 in the first row and the first column is output to the horizontal signal line 21. Thereafter, the selection pulse HSR[1] transitions from the H state to the L state and therefore the column selection transistor M10 is turned off. According to the above-described operation, a difference signal according to the difference between the reset level and the signal level of the pixel 3 in the first row and the first column is read.

Thereafter, the selection pulse HSR[2] transitions from the L state to the H state. Thereby, as in the above-described operation, a difference signal according to the difference between the reset level and the signal level of the pixel 3 in the first row and the second column is read. Thereafter, the selection pulse HSR[2] transitions from the H state to the L state, and the selection pulse HSR[3] transitions from the L state to the H state. Thereby, as in the above-described operation, a difference signal according to the difference between the reset level and the signal level of the pixel 3 in the first row and the third column is read. Thereafter, the selection pulse HSR[3] transitions from the H state to the L state.

Finally, the selection pulse ϕSel_1 transitions from the H state to the L state and therefore the selection transistor Sel is turned off. Thereby, the selection of the pixel 3 of the first row is canceled and the operation of reading the pixel signal from the pixel 3 of the first row is completed. Following the operation shown in FIG. 15, an operation of reading the pixel signal from the pixel 3 of the second row is performed. This operation is similar to the operation shown in FIG. 15.

The imaging device 1e of the third embodiment includes the AD conversion circuit 10, the imaging unit 2, the column circuit 8e, the reference signal generation circuit 9, the current generation circuit 41 (a first current generation circuit), the current generation Circuit 42 (a second current generation circuit). The imaging unit 2 includes a plurality of pixels 3 disposed in a matrix shape. The column circuit 8e is electrically connected to the imaging unit 2 and generates a difference signal according to a difference between a reset level and a signal level. The reference signal generation circuit 9 generates a reference signal. The current generation circuit 41 is electrically connected to the reference signal generation circuit 9 and generates a second reference current signal according to the reference signal. The current generation circuit 42 is electrically connected to the column circuit 8e and generates a difference current signal according to the difference signal. The arithmetic circuit 12 is electrically connected to one of the current generation circuit 41 and the current generation circuit 42. The arithmetic circuit 12 is electrically connected to the current generation circuit 42. The comparison circuit 13 is electrically connected to the other of the current generation circuit 41 and the current generation circuit 42. The comparison circuit 13 is electrically connected to the current generation circuit 41. The first current signal is one of the second reference current signal and the difference current signal. The first current signal is the difference current signal. The second current signal is the other of the second reference current signal and the difference current signal. The second current signal is the second reference current signal.

The imaging device of each aspect of the present invention need not have configurations other than configurations corresponding to the AD conversion circuit 10, the imaging section 2, the column circuit 8e, the reference signal generation circuit 9, the current generation circuit 41, and the current generation circuit 42.

The imaging device 1e of the third embodiment includes a smaller AD conversion circuit 10. Therefore, it is possible to further reduce a size of the imaging device 1e. The imaging device 1e can perform AD conversion on the difference signal.

The reference signal generation circuit 9 generates a reference signal including a component according to the change in the power-supply voltage, thereby reducing an influence of a component according to a change in the power-supply voltage on the digital data. Thus, the AD conversion circuit 10 can perform AD conversion with higher accuracy. Accordingly, it is possible to implement the imaging device 1e having a high power supply rejection ratio (PSRR).

### First Modified Example of Third Embodiment

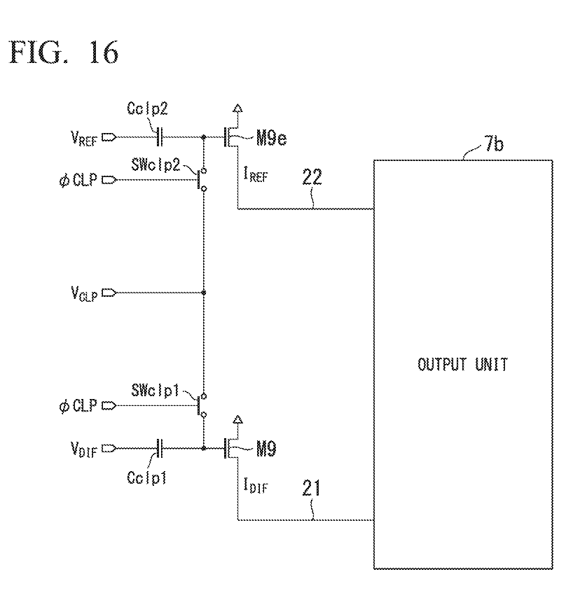

In an imaging device 1e of a first modified example of the third embodiment of the present invention, the output unit 7 is changed to an output unit 7b shown in FIG. 16. FIG. 16 shows a configuration of the output unit 7b. The configuration of the output unit 7b shown in FIG. 16 is the same as that of the output unit 7b shown in FIG. 8. Thus, a detailed description of the configuration of the output unit 7b will be omitted.

Connections between the current generation circuit 41A, the current generation circuit 41B, the current generation circuit 42A, and the current generation circuit 42B to the horizontal signal line 21 and the horizontal signal line 22 are different from the connections shown in FIG. 8. A drain terminal of a transistor N1A is connected to the horizontal signal line 22, and a drain terminal of a transistor N3A is connected to the horizontal signal line 21.

The output unit 7b includes an interleaved AD conversion circuit 10b. Thus, the AD conversion circuit 10b and the in device 1e can perform AD conversion at higher speed.

### Second Modified Example of Third Embodiment

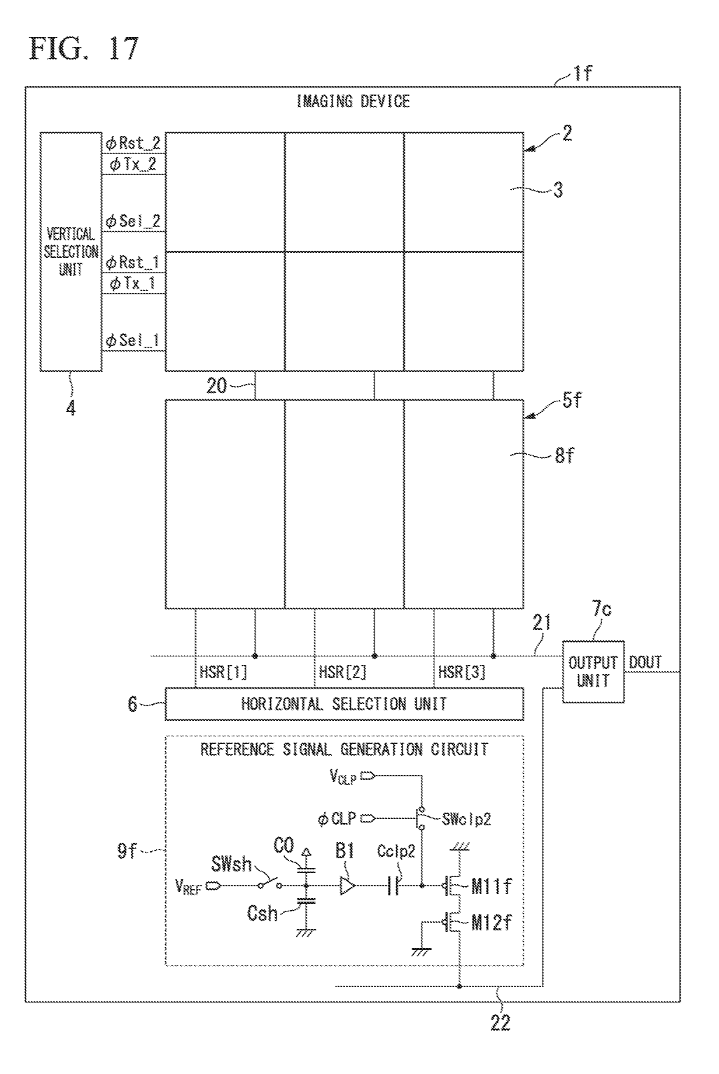

FIG. 17 shows a configuration of an imaging device 1f according to a second modified example of the third embodiment of the present invention. The configuration shown in FIG. 17 will be described in terms of differences from the configuration shown in FIG. 12.

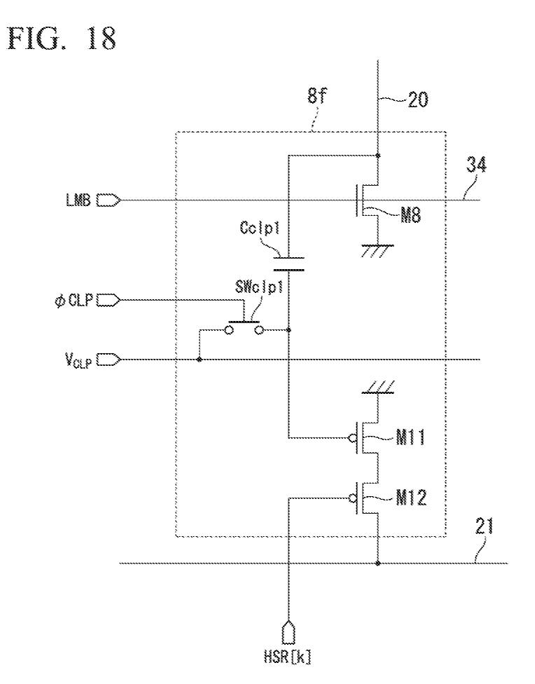

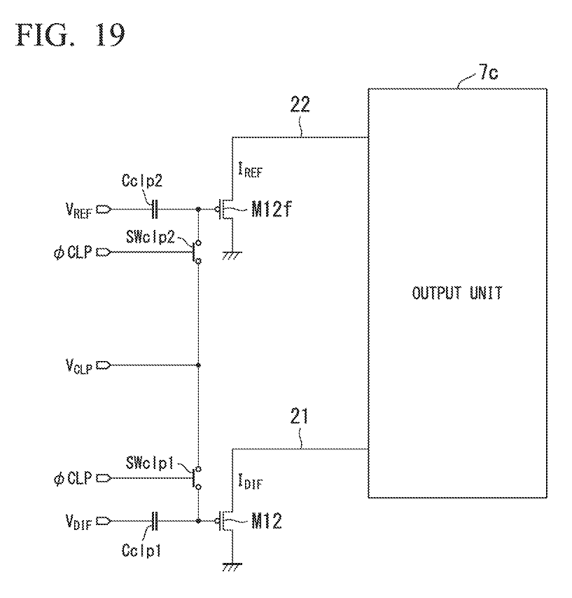

In the imaging device 1f, the column circuit unit 5e in the imaging device 1e shown in FIG. 12 is changed to a column circuit unit 5f. In the column circuit unit 5f, the column circuit 8e in the column circuit unit 5e shown in FIG. 12 is changed to a column circuit 8f shown in FIG. 18. In the imaging device 1f, the reference signal generation circuit 9 is changed to a reference signal generation circuit 9f, and the output unit 7 is changed to an output unit 7c shown in FIG. 19. In the reference signal generation circuit 9f, the amplification transistor M9e in the reference signal generation circuit 9 shown in FIG. 12 is changed to an amplification transistor M11f, and the selection transistor M10e in the reference signal generation circuit 9 shown in FIG. 12 is changed to a selection transistor M12f.

The amplification transistor M11f and the selection transistor M12f are PMOS transistors. Each of the amplification transistor M11f and the selection transistor M12f includes a gate terminal, a source terminal, and a drain terminal. The drain terminal the amplification transistor M11f is connected to the ground. The source terminal of the amplification transistor M11f is connected to the selection transistor M12f. The gate terminal of the amplification transistor M11f is connected to a second terminal of a capacitive element Cclp2.

The drain terminal of the selection transistor M12f is connected to the source terminal of the amplification transistor M11f. The source terminal of the selection transistor M12f is connected to the horizontal signal line 22. The gate terminal of the selection transistor M12f is connected to the ground.

In terms of details other than the above, the configuration shown in FIG. 17 is similar to the configuration shown in FIG. 12.

FIG. 18 shows the configuration of the column circuit 8f. In terms of the configuration shown in FIG. 18, differences from the configuration shown in FIG. 13 will be described.

In the column circuit 8f, the amplification transistor M9 in the column circuit 8e shown in FIG. 13 is changed to an amplification transistor M11 and the column selection transistor M10 in the column circuit 8e shown in FIG. 13 is changed to a column selection transistor M12.

The amplification transistor M11 and the column selection transistor M12 are PMOS transistors. Each of the amplification transistor M11 and the column selection transistor M12 includes a gate terminal, a source terminal, and a drain terminal. The drain terminal of the amplification transistor M11 is connected to the ground. The source terminal of the amplification transistor M11 is connected to the column selection transistor M12. The gate terminal of the amplification transistor M11 is connected to the second terminal of the capacitive element Cclp1.

The drain terminal of the column selection transistor M12 is connected to the source terminal of the amplification transistor M11. The source terminal of the column selection transistor M12 is connected to the horizontal signal line 21. The gate terminal of the column selection transistor M12 is connected to the horizontal selection unit 6.

In terms of details other than the above, the configuration shown in FIG. 18 is similar to the configuration shown in FIG. 13.

FIG. 19 shows a configuration of the output unit 7c. The configuration of the output unit 7c shown in FIG. 19 is the same as that of the output unit 7c shown in FIG. 10. Thus, a detailed description of the configuration of the output unit 7c will be omitted. In the description of this modified example, the current value (I_{REF}) of the reference signal is assumed to be smaller than the current value (I_{DIF}) of the difference signal.

As shown in FIG. 10, the output unit 7c includes an AD conversion circuit 10a, a current generation circuit 41c, and a current generation circuit 42c. The AD conversion circuit 10a includes a DA conversion circuit 11, an arithmetic circuit 12a, and a comparison circuit 13a. The arithmetic circuit 12a generates a comparison current signal by subtracting a first reference current signal (I_{DAC}) from a first current signal (I_{DIF}). The comparison circuit 13a outputs digital data based on a result of comparing the second current signal (I_{REF}) with the comparison current signal.

The operation of the imaging device 1f is similar to the operation of the imaging device 1 shown in FIG. 3. Thus, a detailed description of the operation of the imaging device 1f will be omitted.

The imaging device 1f of the second modified example of the third embodiment has a smaller AD conversion circuit 10a. Thus, it is possible to further reduce a size of the imaging device 1f. The imaging device 1f can perform AD conversion on the difference signal.

The reference signal generation circuit 9f generates a reference signal including a component according to a change in a power-supply voltage, thereby reducing an influence of the component according to the change in the power-supply voltage on the digital data. Thus, the AD conversion circuit 10a can perform AD conversion with higher accuracy. Therefore, it is possible to implement the imaging device 1f with a high PSRR.

### Third Modified Example of Third Embodiment

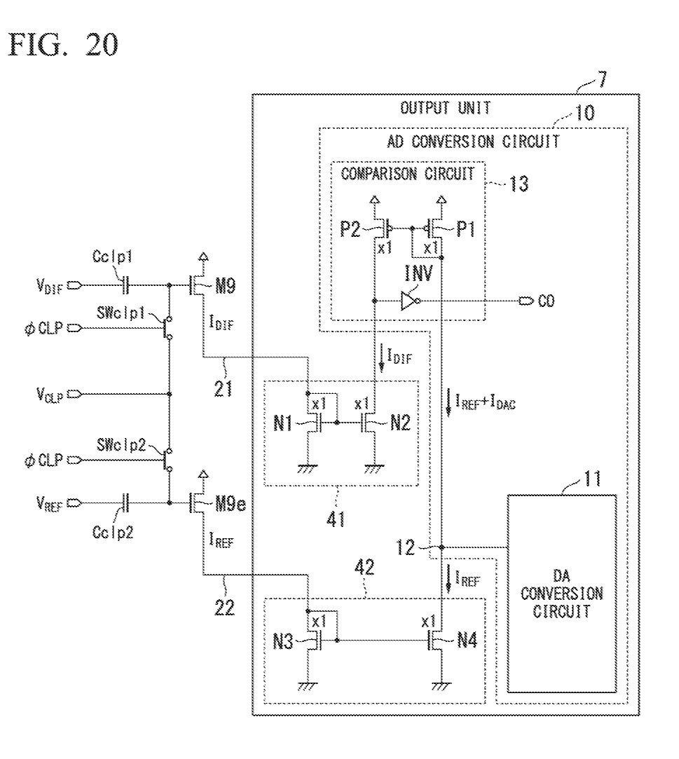

FIG. 20 shows a configuration of an output unit 7 of an imaging device 1e of a third modified example of the third embodiment of the present invention. The configuration of the output unit 7 shown in FIG. 20 is the same as that of the output unit 7 shown in FIG. 6. Thus, a detailed description of the configuration of the output unit 7 will be omitted.

Connections of a current generation circuit 41 and a current generation circuit 42 to a horizontal signal line 21 and a horizontal signal line 22 are different from those shown in FIG. 14. A drain terminal of a transistor N1 is connected to the horizontal signal line 21 and a drain terminal of a transistor N3 is connected to the horizontal signal line 22. The current generation circuit 41 is electrically connected to a column circuit 8e via the horizontal signal line 21. The current generation circuit 42 is electrically connected to a reference signal generation circuit 9 via the horizontal signal line 22.

A reference signal output from an amplification transistor M9e of the reference signal generation circuit 9 to the horizontal signal line 22 via a selection transistor M10e is input to the current generation circuit 42. In FIG. 20, the selection transistor M10e is not shown. The reference signal is based on a voltage (V_{REF}) of a second terminal of a capacitive element Cclp2. The current value of the reference signal is I_{REF}. The reference signal flows between the drain terminal of the transistor N3 and a source terminal of the transistor N3. A transistor N4 generates a second reference current signal by returning the reference signal flowing through the transistor N3 in accordance with a mirror ratio of the transistor N3 and the transistor N4. In this example, a current whose current value is the same as the current value (I_{REF}) of the reference signal flows between the drain terminal of the transistor N4 and the source terminal of the transistor N4. The second reference current signal generated by the transistor N4 is supplied as a first current signal to an arithmetic circuit 12.

The difference signal output from the amplification transistor M9 of the column circuit 8e to the horizontal signal line 21 via the column selection transistor M10 is input to the current generation circuit 41. In FIG. 20, the column selection transistor M10 is not shown. The difference signal is based on a difference (V_{DIF}) between a reset level and a signal level. The current value of the difference signal is I_{DIF}. In the description of this modified example, the current value (I_{REF}) of the reference signal is assumed to be smaller than the current value (I_{DIF}) of the difference signal. The difference signal flows between the drain terminal of the transistor N1 and the source terminal of the transistor N1. The transistor N2 generates a difference current signal by returning the difference signal flowing through the transistor N1 in accordance with the mirror ratio of the transistor N1 and the transistor N2. In this example, a current whose current value is the same as the current value (I_{DIF}) of the difference signal flows between the drain terminal of the transistor N2 and the source terminal of the transistor N2. The difference current signal generated by the transistor N2 is supplied as a second current signal to the comparison circuit 13.

An operation of an AD conversion circuit 10 is similar to the operation of the AD conversion circuit 10 shown in FIG. 1. Thus, a detailed description of the operation of the AD conversion circuit 10 will be omitted.

Instead of the output unit 7, the output unit 7c shown in FIG. 10 may be used.

In the imaging device 1e according to the third modified example of the third embodiment, the current generation circuit 42 (a first current generation circuit) is electrically connected to the reference signal generation circuit 9 and generates the second reference current signal according to a reference signal. The current generation circuit 41 (a second current generation circuit) is electrically connected to the column circuit 8e and generates a difference current signal according to a difference signal. The arithmetic circuit 12 is electrically connected to one of the current generation circuit 41 and the current generation circuit 42. The arithmetic circuit 12 is electrically connected to the current generation circuit 42. The comparison circuit 13 is electrically connected to the other of the current generation circuit 41 and the current generation circuit 42. The comparison circuit 13 is electrically connected to the current generation circuit 41. The first current signal is one of the second reference current signal and the difference current signal. The first current signal is the second reference current signal. The second current signal is the other of the second reference current signal and the difference current signal. The second current signal is the difference current signal.

The imaging device 1e of the third modified example of the third embodiment has a more compact AD conversion circuit 10. Therefore, it is possible to further reduce a size of the imaging device 1e. The imaging device 1e can perform AD conversion on the difference signal.

The reference signal generation circuit 9 generates a reference signal including a component according to a change in the power-supply voltage, thereby reducing an influence of the component according to the change in the power-supply voltage on the digital data. Thus, the AD conversion circuit 10 can perform AD conversion with higher accuracy. Therefore, it is possible to implement the imaging device 1e with a high PSRR.

### Fourth Modified Example of Third Embodiment

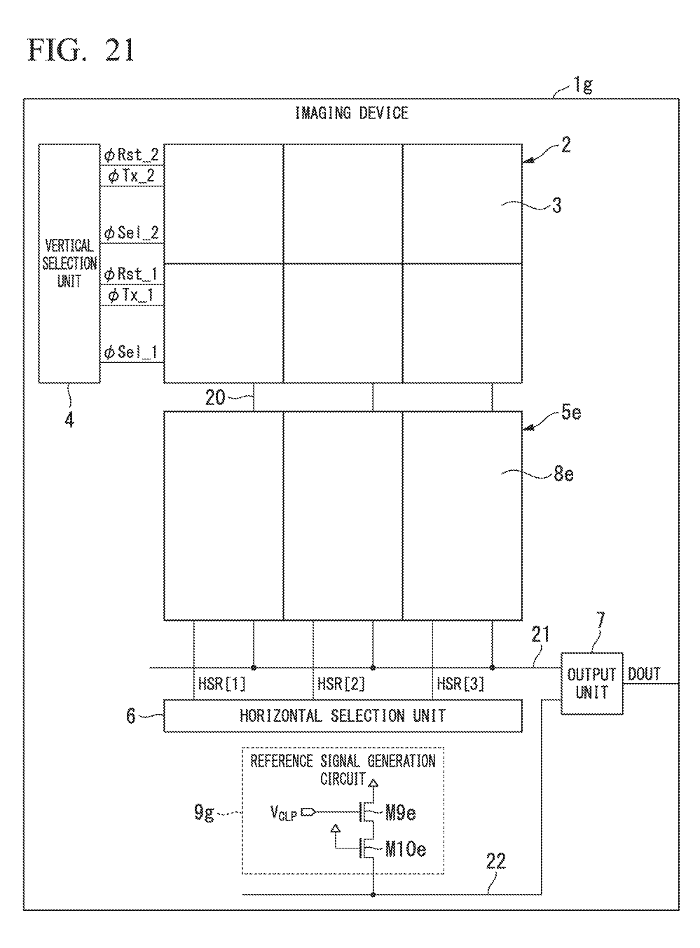

FIG. 21 shows a configuration of an imaging device 1g according to a fourth modified example of the third embodiment of the present invention. The configuration shown in FIG. 21 will be described in terms of differences from the configuration shown in FIG. 12.

In the imaging device 1g, the reference signal generation circuit 9 in the imaging device 1e shown in FIG. 12 is changed to a reference signal generation circuit 9g. The reference signal generation circuit 9g includes an amplification transistor M9e and a selection transistor M10e.

A gate terminal of the amplification transistor M9e is connected to a power supply configured to output a clamp voltage. The voltage value of the clamp voltage is V_{CLP}.

In terms of details other than the above, the configuration shown in FIG. 21 is similar to the configuration shown in FIG. 12.

It is only necessary for a current value of the reference signal generated by the reference signal generation circuit 9g to be a value for inverting a signal CO output from an inverter circuit INV in accordance with an increase or a decrease in a current value (I_{DAC}) of a first reference current signal in the AD conversion circuit 10.

An operation of the imaging device 1g is similar to the operation of the imaging device 1 shown in FIG. 3. Thus, a detailed description of the operation of the imaging device 1g will be omitted.

In the imaging device 1e of the first modified example of the third embodiment, the reference signal generation circuit 9g may be used instead of the reference signal generation circuit 9. In the imaging device 1f of the second modified example of the third embodiment, a circuit similar to the reference signal generation circuit 9g may be used instead of the reference signal generation circuit 9f. The reference signal generation circuit 9g may be used instead of the reference signal generation circuit 9 in the imaging device 1e of the third modified example of the third embodiment.

The imaging device 1g according to the fourth modified example of the third embodiment has a smaller AD conversion circuit 10. Thus, it is possible to further reduce the size of the imaging device 1g. The imaging device 1g can perform AD conversion on the difference signal.

Compared with the imaging device 1g shown in FIG. 21, the imaging device 1e shown in FIG. 12 easily reduces a component a according to a change in the power-supply voltage. On the other hand, a circuit area of the reference signal generation circuit 9g shown in FIG. 21 is smaller than the circuit area of the reference signal generation circuit 9 shown in FIG. 12. Thus, it is possible to further reduce a size of the imaging device 1g.

### Fourth Embodiment

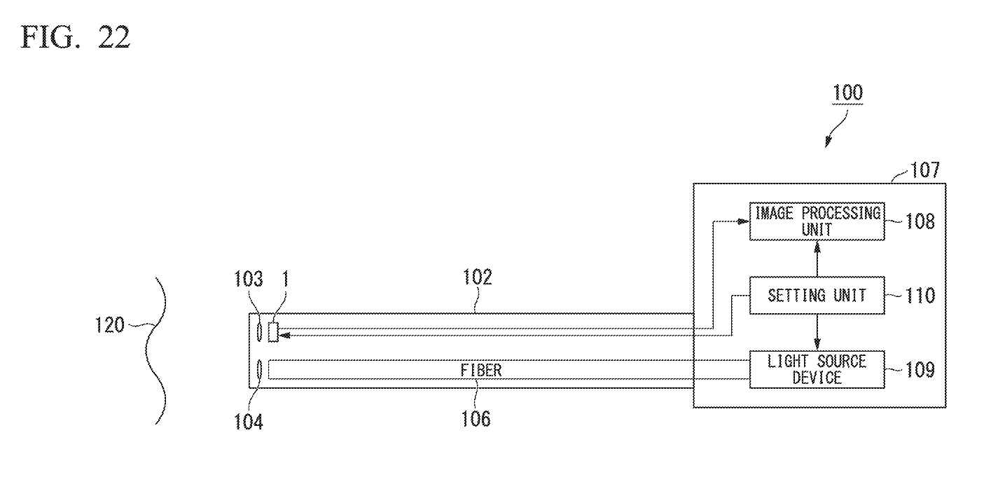

FIG. 22 shows a configuration of an endoscope system 100 according to a fourth embodiment of the present invention. The endoscope system 100 includes the imaging device 1 of the second embodiment. As shown in FIG. 22, the endoscope system 100 includes a scope 102 and a housing 107. The scope 102 has an imaging device 1, a lens 103, a lens 104, and a fiber 106. The housing 107 includes an image processing unit 108, a light source device 109, and a setting unit 110.

The imaging device 1 is the imaging device 1 of the second embodiment. The lens 103 forms an image of reflected light from a subject 120 on the imaging device 1. The fiber 106 transmits illumination light radiated to the subject 120. The lens 104 irradiates the subject 120 with the illumination light transmitted by the fiber 105. The light source device 109 includes a light source configured to generate illumination light to be radiated to the subject 120. The image processing unit 108 generates a captured image by performing a predetermined process on a signal output from the imaging device 1. The image processing unit 108 includes a circuit corresponding to a subsequent-stage circuit 200. The setting unit 110 controls an imaging mode of the endoscope system 100.

The configuration of the endoscope system 100 is not limited to the above-described configuration. The endoscope system of each embodiment of the present invention need not have a configuration corresponding to at least one of the lens 103, the lens 104, the fiber 106, the image processing unit 108, the light source device 109, and the setting unit 110.

Instead of the imaging device 1, any one of the imaging device 1e shown in FIG. 12, the imaging device 1f shown in FIG. 17, and the imaging device 1g shown in FIG. 21 may be used.

The endoscope system 100 according to the fourth embodiment has a smaller imaging device 1. Thus, it is possible to further reduce a size of the endoscope system 100.

While preferred embodiments of the invention have been described and shown above, it should be understood that these are exemplars of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. An analog-to digital (AD) conversion circuit, comprising:
a digital-to-analog (DA) conversion circuit configured to generate a first reference current signal;
an arithmetic circuit electrically connected to the DA conversion circuit and configured to generate a comparison current signal by adding the first reference current signal to a first current signal generated in accordance with a first voltage signal or subtracting the first reference current signal from the first current signal; and
a comparison circuit electrically connected to the arithmetic circuit and configured to output digital data based on a result of comparing a second current signal according to a second voltage signal with the comparison current signal.

2. An imaging device, comprising:
the AD conversion circuit according to claim 1;
an imaging unit including a plurality of pixels disposed in a matrix shape, each pixel included in the plurality of pixels configured to output a reset level and a signal level;
a column circuit electrically connected to the imaging unit and configured to generate a first pixel signal according to the reset level yard a second pixel signal according to the signal level;
a first current generation circuit electrically connected to the column circuit and configured to generate a first pixel current signal according to the first pixel signal; and
a second current generation circuit electrically connected to the column circuit and configured to generate a second pixel current signal according to the second pixel signal,
wherein the arithmetic circuit is further electrically connected to one of the first current generation circuit and the second current generation circuit,
the comparison circuit is further electrically connected to the other of the first current generation circuit and the second current generation circuit,
the first current signal is one of the first pixel current signal and the second pixel current signal, and
the second current signal is the other of the first pixel current signal and the second pixel current signal.

3. The imaging device according to claim 2,
wherein the first current generation circuit includes a first transistor and a second transistor constituting a first current mirror circuit, and
the second current generation circuit includes a third transistor and a fourth transistor constituting a second current mirror circuit different from the first current mirror circuit.

4. An imaging device, comprising:
the AD conversion circuit according to claim 1;
an imaging unit including a plurality of pixels disposed in a matrix shape, each pixel included in the plurality of pixels configured to output a reset level and a signal level;
a column circuit electrically connected to the imaging unit and configured to generate a difference signal according to a difference between the reset level and the signal level;
a reference signal generation circuit configured to generate a reference signal;
a first current generation circuit electrically connected to the reference signal generation circuit and configured to generate a second reference current signal according to the reference signal; and
a second current generation circuit electrically connected to the column circuit and configured to generate a difference current signal according to the difference signal,
wherein the arithmetic circuit is further electrically connected to one of the first current generation circuit and the second current generation circuit,
the comparison circuit is further electrically connected to the other of the first current generation circuit and the second current generation circuit,
the first current signal is one of the second reference current signal and the difference current signal, and
the second current signal is the other of the second reference current signal and the difference current signal.

5. The imaging device according to claim 4,
wherein the first current generation circuit includes a first transistor and a second transistor constituting a first current mirror circuit, and
the second current generation circuit includes a third transistor and a fourth transistor constituting a second current mirror circuit different from the first current mirror circuit.
